(19) United States
(12) Patent Application Publication
(10) Pub. No.: US 2023/0170441 A1
(43) Pub. Date: Jun. 1, 2023

(54) LIGHT EMITTING DEVICE AND DISPLAY APPARATUS COMPRISING SAME

(71) Applicant: Samsung Display Co., LTD., Yongin-si, Gyeonggi-do (KR)

(72) Inventors: Mi Hyang SHEEN, Asan-si (KR); Sang Hyung LIM, Cheonan-si (KR); Myeong Kyu PARK, Suwon-si (KR); Na Ri AHN, Seongnam-si (KR); Doo Hyoung LEE, Suwon-si (KR)

(21) Appl. No.: 17/997,519

(22) PCT Filed: Apr. 23, 2021
(86) PCT No.: PCT/KR2021/005157

§ 371 Date: Oct. 28, 2022

(30) Foreign Application Priority Data
Apr. 29, 2020 (KR) 10-2020-0052062

(51) Int. Cl. H01L 33/38; H01L 33/24; H01L 33/60; H01L 33/62; H01L 25/075

(52) U.S. Cl. CPC H01L 33/382; H01L 25/0753; H01L 33/24; H01L 33/60; H01L 33/62

(57) ABSTRACT

Provided are a light emitting device and a display apparatus comprising the same. The light emitting device comprises a light emitting device core extending in one direction, and a transmission filter layer surrounding a part of the side surface of the light emitting device core, wherein the side surface of the light emitting device core comprises a first area having the transmission filter layer arranged therein, and a second area not having the transmission filter layer arranged therein.

### CROSS REFERENCE TO RELATED APPLICATION(S)

This application is a U.S. National Phase Patent Application of International Application No. PCT/KR2021/005157, filed on Apr. 23, 2021, which claims priority to Korean Patent Application No. 1 0-2020-0052062, filed on Apr. 29, 2020, the entire contents of which are incorporated herein by reference.

### FIELD

The present disclosure relates to a light emitting device and a display apparatus including the same.

### DESCRIPTION OF RELATED ART

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The light emitting display panel may include light emitting elements, e.g., light emitting diodes (LED), and examples of the light emitting diode include an organic light emitting diode (OLED) using an organic material as a fluorescent material and an inorganic light emitting diode using an inorganic material as a fluorescent material.

### SUMMARY

The present disclosure is directed to providing a light emitting device in which light efficiency in one direction is increased.

The present disclosure is also directed to providing a display apparatus including a light emitting device in which light efficiency in one direction is increased.

It should be noted that aspects of the disclosure are not limited thereto and other aspects, which are not mentioned herein, will be apparent to those of ordinary skill in the art from the following description.

According to one or more embodiments of the disclosure, a light emitting device comprises a light emitting device core extending along one direction, and a transmission filter layer surrounding a part of a side surface of the light emitting device core, wherein the side surface of the light emitting device core includes a first area in which the transmission filter layer is located, and a second area in which the transmission filter layer is not located.

The transmission filter layer may have different reflectances depending on an incident angle based on a wavelength and a normal direction of incident light.

The transmission filter layer may include one or more optical layers, wherein the optical layers may include a first inorganic film having a first refractive index and a second inorganic film having a second refractive index different from the first refractive index, which are sequentially stacked on the second area in a direction perpendicular to the one direction.

The first refractive index may be less than the second refractive index.

The light emitting device core may include a first semiconductor layer, a second semiconductor layer, and an active layer located between the first semiconductor layer and the second semiconductor layer.

The first semiconductor layer, the active layer, and the second semiconductor layer may be sequentially located along the one direction.

The light emitting device core may further include a first electrode layer located on the first semiconductor layer, and a second electrode layer located on the second semiconductor layer, wherein each of the first electrode layer and the second electrode layer may include a conductive material having a high reflectance.

The second area may include at least a part of a side surface of the active layer.

The light emitting device may further comprise a reflective film surrounding an outer circumferential surface of the transmission filter layer.

A surface of the second area may be exposed by the transmission filter layer.

An outer circumferential length of the first area may be greater than an outer circumferential length of the second area.

A length of the first area in the one direction may be equal to a length of the light emitting device core in the one direction.

A maximum length of the second area in the one direction may be less than the length of the first area in the one direction.

A thickness of the transmission filter layer located in an area adjacent to the second area may decrease from the first area toward the second area.

A surface of the second area may include a surface unevenness.

The transmission filter layer may be in direct contact with the first area.

According to one or more embodiments of the disclosure, a display apparatus comprises a substrate, a first electrode located on the substrate, a second electrode located on the substrate to be spaced apart from the first electrode, a light emitting device located between the first electrode and the second electrode and electrically connected to the first electrode and the second electrode, and an insulating layer located on the light emitting device, wherein the light emitting device includes a light emitting device core extending along one direction, and a transmission filter layer surrounding a part of a side surface of the light emitting device core, wherein the side surface of the light emitting device core includes a first area in which the transmission filter layer is located, and a second area in which the transmission filter layer is not located.

The one direction may be parallel to an upper surface of the substrate, and the light emitting device may be located such that the second area faces a side opposite to one side facing the substrate.

The first area may be located on the one side facing the substrate, and the transmission filter layer may be located between the light emitting device core and the substrate.

The insulating layer may be in contact with the second area.

The details of other embodiments are included in the detailed description and the accompanying drawings.

A light emitting device according to one or more embodiments includes a light emitting device core and a transmission filter layer surrounding a part of a side surface of the light emitting device core. By placing the transmission filter layer on a part of the side surface of the light emitting device core, it is possible to control a traveling direction of transmitted light L for light that is generated in the light emitting device core and randomly travels without directionality. For example, by placing the transmission filter layer in a direction opposite to a display direction of a display apparatus, light, which is emitted from an active layer and travels in a downward direction with respect to a substrate, is allowed to travel in an upward direction with respect to the substrate, so that the loss of light can be reduced or minimized. Accordingly, light emitting efficiency of the display apparatus can be improved.

The aspects according to one or more embodiments are not limited by the contents exemplified above, and more various aspects are included in this disclosure.

### BRIEF DESCRIPTION OF THE DRAWINGS

FIG. 1 is a plan view of a display apparatus according to one or more embodiments.

FIG. 2 is a plan view illustrating one pixel of the display apparatus according to one or more embodiments.

FIG. 3 is a schematic perspective view of a light emitting device according to one or more embodiments.

FIG. 4 is a cross-sectional view of the light emitting device according to one or more embodiments, and is a cross-sectional view taken along the line IV-IV′ of FIG. 3.

FIG. 5 is a cross-sectional view of the light emitting device according to one or more embodiments, and is a cross-sectional view taken along the line V-V′ of FIG. 3.

FIG. 6 is an enlarged cross-sectional view of portion A of FIG. 3.

FIG. 7 is a schematic view illustrating a traveling direction of light generated in the light emitting device according to one or more embodiments.

FIG. 8 is a schematic cross-sectional view taken along the line VIII-VIII′ of FIG. 2.

FIG. 9 is a schematic cross-sectional view taken along the line IX-IX′ of FIG. 2.

FIGS. 10 to 17 are cross-sectional views illustrating a manufacturing process of the light emitting device according to one or more embodiments.

FIG. 18 is a cross-sectional view illustrating another example of the light emitting device taken along the line V-V′ of FIG. 3.

FIG. 19 is a cross-sectional view illustrating still another example of the light emitting device taken along the line V-V′ of FIG. 3.

FIG. 20 is a cross-sectional view illustrating yet another example of the light emitting device taken along the line V-V′ of FIG. 3.

FIG. 21 is a cross-sectional view of a light emitting device according to one or more other embodiments.

FIG. 22 is a schematic cross-sectional view illustrating that the light emitting device of FIG. 21 is located on electrodes.

FIG. 23 is a cross-sectional view of a light emitting device according to still one or more other embodiments.

FIG. 24 is a schematic perspective view of a light emitting device according to yet one or more other embodiments.

FIG. 25 is a schematic cross-sectional view taken along the line XXV-XXV’ of FIG. 24.

FIG. 26 is a cross-sectional view illustrating an example taken along the line XXVI-XXVI′ of FIG. 2.

FIG. 27 is an enlarged cross-sectional view illustrating an example of portion Q1 of FIG. 26.

FIG. 28 is an enlarged cross-sectional view illustrating another example of portion Q1 of FIG. 26.

FIG. 29 is a cross-sectional view illustrating another example taken along the line XXVI-XXVI′ of FIG. 2.

FIG. 30 is an enlarged cross-sectional view illustrating an example of portion Q2 of FIG. 29.

FIG. 31 is a schematic perspective view of a light emitting device according to yet one or more other embodiments.

FIG. 32 is a cross-sectional view of the light emitting device of FIG. 31.

FIG. 33 is a schematic perspective view of a light emitting device according to yet one or more other embodiments.

FIG. 34 is a cross-sectional view of the light emitting device of FIG. 33.

FIG. 35 is a schematic perspective view of a light emitting device according to yet one or more other embodiments.

FIG. 36 is a schematic cross-sectional view taken along the line XXXVI-XXXVI′ of FIG. 35.

FIG. 37 is a schematic perspective view of a light emitting device according to yet one or more other embodiments.

FIG. 38 is a schematic cross-sectional view taken along the line XXXVIII-XXXVIII′ of FIG. 37.

### DETAILED DESCRIPTION

The present disclosure will now be described more fully hereinafter with reference to the accompanying drawings, in which embodiments of the present disclosure are shown. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Hereinafter, embodiments will be described with reference to the accompanying drawings.

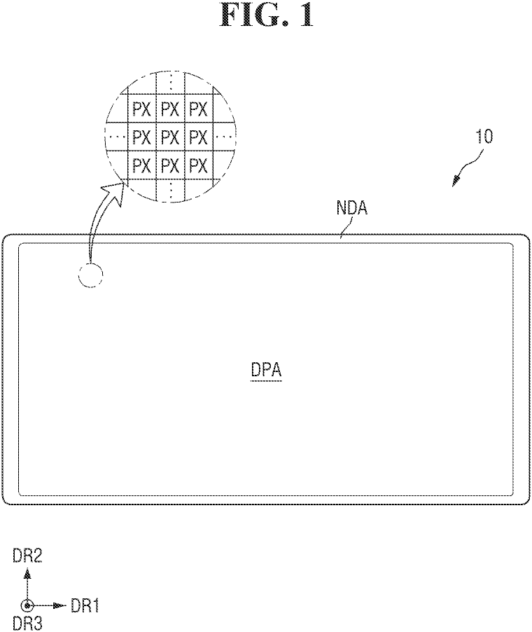

FIG. 1 is a plan view of a display apparatus according to one or more embodiments.

Referring to FIG. 1, a display apparatus 10 displays a video or a still image. The display apparatus 10 may refer to all electronic apparatuses that provide a display screen. For example, the display apparatus 10 may include a television, a laptop computer, a monitor, a billboard, an Internet of Things device, a mobile phone, a smartphone, a tablet personal computer (PC), an electronic watch, a smartwatch, a watch phone, a head-mounted display, a mobile communication terminal, an electronic organizer, an e-book reader, a portable multimedia player (PMP), a navigation system, a game console, a digital camera, and a camcorder, which are provided with a display screen.

In the drawings, a first direction DR1, a second direction DR2, and a third direction DR3 are defined. The first direction DR1 and the second direction DR2 may be directions perpendicular to each other in one plane. The third direction DR3 may be a direction perpendicular to a plane in which the first direction DR1 and the second direction DR2 are positioned. The third direction DR3 is perpendicular to each of the first direction DR1 and the second direction DR2. In embodiments for describing the display apparatus 10, the third direction DR3 indicates a thickness direction of the display apparatus 10.

The display apparatus 10 includes a display panel that provides a display screen. Examples of the display panel may include an inorganic light emitting diode display panel, an organic light emitting display panel, a quantum dot light emitting display panel, a plasma display panel, a field emission display panel, and the like. Hereinafter, a case in which the inorganic light emitting diode display panel is applied as an example of the display panel is illustrated, but the present disclosure is not limited thereto, and when the same technical spirit is applicable, it may also be applied to other display panels.

The display apparatus 10 may have a rectangular shape including long and short sides in which a side in the first direction DR1 is longer than a side in the second direction DR2 in a plan view. When viewed in a plan view, a corner at which the long side and the short side of the display apparatus 10 meet may be at right angle, but the present disclosure is not limited thereto, and the corner may have a rounded curved shape. The shape of the display apparatus 10 is not limited to the illustrated one and may be variously modified. For example, the display apparatus 10 may have other shapes such as a square shape, a quadrangular shape with round corners (vertexes), other polygonal shapes, and a circular shape in a plan view.

A display surface of the display apparatus 10 may be located at one side of the third direction DR3, which is a thickness direction. In the embodiments, unless otherwise stated, in describing the display apparatus 10, an upper portion or an upper side refers to a display direction as one side of the third direction DR3, and similarly, an upper surface refers to a surface that faces one side of the third direction DR3. In addition, a lower portion or a lower side refers to an opposite direction of the display direction as the other side of the third direction DR3, and a lower surface denotes a surface facing the other side in the third direction DR3.

The display apparatus 10 may include a display area DPA and a non-display area NDA. The display area DPA is an area in which a screen may be displayed, and the non-display area NDA is an area in which a screen is not displayed. The display area DPA may be referred to as an active area, and the non-display area NDA may be referred to as an inactive area.

For example, the shape of the display area DPA may also be a planar rectangular shape similar to an overall shape of the display apparatus 10. The display area DPA may substantially occupy a center of the display apparatus 10.

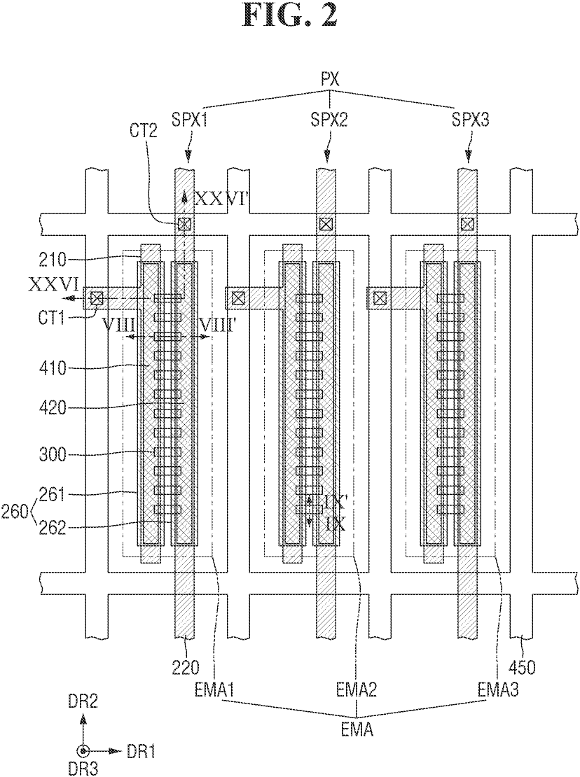

The display area DPA may include a plurality of pixels PX. The plurality of pixels PX may be arranged in a matrix direction. A shape of each of the pixels PX may be a rectangular shape or a square shape in a plan view but is not limited thereto, and the shape may be a rhombus shape of which each side is inclined with respect to one direction. The pixels PX may be alternately arranged as a stripe type or a PenTile™ type (e.g., a PENTILE™ matrix structure or an RGBG structure, PENTILE™ being a registered trademark of Samsung Display Co., Ltd., Republic of Korea). Each pixel PX may include at least one light emitting device 300 (see FIG. 2) configured to emit light of a corresponding wavelength range.

The non-display area NDA may be located around the display area DPA. The non-display area NDA may completely or partially surround the display area DPA. The display area DPA has a rectangular shape, and the non-display area NDA may be located adjacent to four sides of the display area DPA. The non-display area NDA may form a bezel of the display apparatus 10. In the non-display area NDA, lines or circuit drivers included in the display apparatus 10 or a pad part on which an external apparatus is mounted may be located.

FIG. 2 is a plan view illustrating one pixel of the display apparatus according to one or more embodiments.

Referring to FIG. 2, each of the plurality of pixels PX may include a first sub-pixel SPX1, a second sub-pixel SPX2, and a third sub-pixel SPX3.

The first sub-pixel SPX1 may emit light having a first color, the second sub-pixel SPX2 may emit light having a second color, and the third sub-pixel SPX3 may emit light having a third color. For example, the first color may be blue, the second color may be green, and the third color may be red. However, the present disclosure is not limited thereto, and each sub-pixel SPXn may emit light having the same color. In addition, although FIG. 2 illustrates that each pixel PX includes three sub-pixels SPXn, the present disclosure is not limited thereto, and each pixel PX may include a larger number of sub-pixels SPXn.

Each sub-pixel SPXn of the display apparatus 10 may include an area that is defined as a light emitting area EMA. The light emitting area EMA may be defined as an area in which the light emitting device 300 included in the display apparatus 10 is located to emit light in a corresponding wavelength range. The first sub-pixel SPX1 may include a first light emitting area EMA1, the second sub-pixel SPX2 may include a second light emitting area EMA2, and the third sub-pixel SPX3 may include a third light emitting area EMA3.

The light emitting area EMA may include an area in which the light emitting device 300 is located. In addition, the light emitting area EMA may include an area in which light emitted from the light emitting device 300 is reflected or refracted due to another member to be emitted. That is, a plurality of light emitting devices 300 may be located in each sub-pixel SPXn, and an area in which the plurality of light emitting devices 300 are located, and an area adjacent to the area, may form the light emitting area EMA.

Each sub-pixel SPXn may include a non-light emitting area defined as an area other than the light emitting area EMA. The non-light emitting area may be an area in which the light emitting devices 300 are not located and light emitted from the light emitting devices 300 does not reach so that light is not emitted.

Each sub-pixel SPXn of the display apparatus 10 may include the plurality of light emitting devices 300, a plurality of electrodes 210 and 220, a plurality of inner banks 410 and 420, and an outer bank 450.

The outer bank 450 may serve to distinguish adjacent sub-pixels SPXn. The outer bank 450 may be located at a boundary between each of the sub-pixels SPXn. The outer bank 450 may form a grid pattern on the entire surface of the display area DPA. The outer bank 450 may be located to surround some of the plurality of inner banks 410 and 420 and the plurality of electrodes 210 and 220, including an area in which the light emitting devices 300 are located between the plurality of inner banks 410 and 420 and between the plurality of electrodes 210 and 220 included in each sub-pixel SPXn.

The inner banks 410 and 420 may include a first inner bank 410 and a second inner bank 420 located adjacent to a center portion of each pixel PX or sub-pixel SPXn.

The first inner bank 410 and the second inner bank 420 may extend in the second direction DR2, and may be terminated by being spaced apart from each other at a boundary between the sub-pixels SPXn so as not to extend to another sub-pixel SPXn adjacent in the second direction DR2. Accordingly, the first inner bank 410 and the second inner bank 420 may be located in each sub-pixel SPXn to form a pattern on the entire surface of the display apparatus 10.

The first inner bank 410 and the second inner bank 420 may be located to be spaced apart from each other in the first direction DR1. The plurality of light emitting devices 300 may be located in the separated space between the first inner bank 410 and the second inner bank 420 in the first direction DR1. The first inner bank 410 and the second inner bank 420 may form an area in which the plurality of light emitting devices 300 are located. That is, the inner banks 410 and 420 may serve to provide the area in which the light emitting device 300 is located.

In FIG. 2, each sub-pixel SPXn is illustrated as including one first inner bank 410 and one second inner bank 420, but the present disclosure is not limited thereto. In some cases, a greater number of inner banks 410 and 420 may be included depending on the number of the plurality of electrodes 210 and 220 included in each sub-pixel SPXn, which will be described below.

The plurality of electrodes 210 and 220 are respectively located on the inner banks 410 and 420. The plurality of electrodes 210 and 220 may include a first electrode 210 and a second electrode 220.

The first electrode 210 may be located on the first inner bank 410 in each sub-pixel SPXn. The first electrode 210 may be located to overlap the first inner bank 410.

The first electrode 210 may have a shape extending in the second direction DR2. The first electrode 210 may extend in the second direction DR2 and may be terminated by being spaced apart from a boundary between the sub-pixels SPXn so as not to extend to another sub-pixel SPXn adjacent in the second direction DR2. The first electrode 210 may be located to be partially spaced apart from the outer bank 450 that surrounds each sub-pixel SPXn.

The first electrode 210 may further include an area located to overlap the outer bank 450. The first electrode 210 may be electrically connected to a driving transistor, which will be described below, through a first contact hole CT1 in the area overlapping the outer bank 450.

The second electrode 220 may be located on the second inner bank 420 in each sub-pixel SPXn. The second electrode 220 may be located to overlap the second inner bank 420.

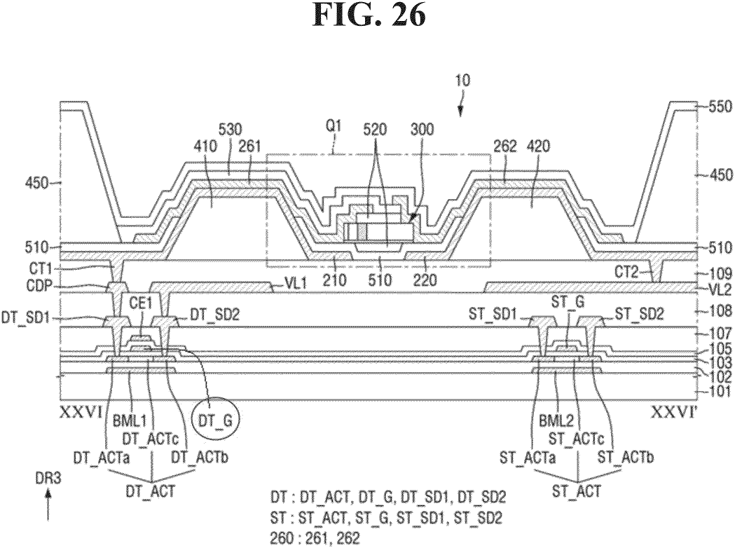

The second electrode 220 may have a shape extending in the second direction DR2. Unlike the first electrode 210, the second electrode 220 may be located to extend to another sub-pixel SPXn adjacent in the second direction DR2. That is, one connected second electrode 220 may be located in the plurality of sub-pixels SPXn adjacent in the second direction DR2. The second electrode 220 may partially overlap the outer bank 450 at a boundary of the sub-pixels SPXn adjacent in the second direction DR2. The second electrode 220 may be electrically connected to a second voltage line VL2 (see FIG. 26), which will be described below, through a second contact hole CT2 in an area overlapping the outer bank 450.

The shape and arrangement structure of the plurality of electrodes 210 and 220 may be variously modified. For example, each of the first electrode 210 and the second electrode 220 may further include a stem portion extending in the first direction DR1. In the first electrode 210, different stem portions may be located for each sub-pixel SPXn, and in the second electrode 220, one stem portion extends to the sub-pixels SPXn adjacent in the first direction DR1 so that the second electrodes 220 of the sub-pixels SPXn may be electrically connected to each other through the stem portion. In this case, the second electrode 220 may be electrically connected to a second voltage line VL2 (see FIG. 26) in the non-display area NDA positioned at a peripheral portion of the display area DPA in which the plurality of pixels PX or sub-pixels SPXn are located.

In the drawing, it is illustrated that the second electrode 220 extends in the second direction DR2 and is located to extend to another sub-pixel SPXn adjacent in the second direction DR2, but the present disclosure is not limited thereto. For example, like the first electrode 210, the second electrode 220 may extend in the second direction DR2 and may be terminated by being spaced apart from the boundary between the sub-pixels SPXn so as not to extend to another sub-pixel SPXn adjacent in the second direction DR2.

Meanwhile, in the drawing, it is illustrated that one first electrode 210 and one second electrode 220 are located in each sub-pixel SPXn, but the present disclosure is not limited thereto. A larger number of first electrodes 210 and second electrodes 220 may be located in each sub-pixel SPXn. For example, the first electrode 210 and the second electrode 220 may each have a partially curved or bent shape, and one electrode of the first electrode 210 and the second electrode 220 may also be located to surround the other electrode thereof. As long as at least a partial area of the first electrode 210 and at least a partial area of the second electrode 220 are spaced apart from each other and face each other to form an area in which the light emitting device 300 is to be located therebetween, the arrangement structures and shapes of the first electrode 210 and the second electrode 220 are not particularly limited.

The plurality of electrodes 210 and 220 may be electrically connected to the light emitting devices 300 and may receive a voltage (e.g., predetermined voltage) to allow the light emitting device 300 to emit light. For example, the plurality of electrodes 210 and 220 may be electrically connected to the light emitting device 300 through contact electrodes 260, which will be described below, and may transmit an electrical signal applied to each of the electrodes 210 and 220 to the light emitting device 300 through the contact electrodes 260.

In one or more embodiments, the first electrode 210 may be a pixel electrode that is separated for each sub-pixel SPXn, and the second electrode 220 may be a common electrode that is commonly connected along each sub-pixel SPXn. Any one of the first electrode 210 and the second electrode 220 may be an anode of the light emitting device 300, and the other one thereof may be a cathode of the light emitting device 300. However, the present disclosure is not limited thereto, and the reverse may be the case. In addition, as described above, the first electrode 210 and the second electrode 220 may be located to be separated for each sub-pixel SPXn.

The plurality of electrodes 210 and 220 may be utilized to form an electric field in the sub-pixel SPXn, thereby aligning the light emitting device 300. The light emitting device 300 may be aligned to be located between the first electrode 210 and the second electrode 220 through the electric field between the first electrode 210 and the second electrode 220, which is formed by applying alignment signals to the first electrode 210 and the second electrode 220.

The light emitting devices 300 may be sprayed onto the first electrode 210 and the second electrode 220 in a state of being dispersed in an ink through an inkjet printing process. The light emitting devices 300, which are sprayed in a state of being dispersed in the ink, may be aligned between the first electrode 210 and the second electrode 220 due to a dielectrophoretic force formed by applying the alignment signals to the first electrode 210 and the second electrode 220.

As described above, the first electrode 210 and the second electrode 220 may be located on the first inner bank 410 and the second inner bank 420, respectively. The first electrode 210 and the second electrode 220 respectively located on the first inner bank 410 and the second inner bank 420 may be spaced apart from each other and face each other. In each of the plurality of light emitting devices 300 located between the first inner bank 410 and the second inner bank 420, at least one end portion may be electrically connected to the first electrode 210 and/or the second electrode 220.

The light emitting device 300 may be located in an area formed between the first electrode 210 and the second electrode 220, or between the first inner bank 410 and the second inner bank 420. One end portion of the light emitting device 300 may be electrically connected to the first electrode 210, and the other end portion thereof may be electrically connected to the second electrode 220. The light emitting device 300 may be electrically connected to each of the first electrode 210 and the second electrode 220 through the contact electrodes 260.

The plurality of light emitting devices 300 may be located to be spaced apart from each other and aligned substantially parallel to each other. An interval at which the light emitting devices 300 are spaced apart is not particularly limited. The plurality of light emitting devices 300 may be oriented and aligned in one direction with a nonuniform density.

The light emitting device 300 may have a shape extending in one direction. The extending direction of the light emitting device 300, which is located between the electrodes 210 and 220, may be substantially perpendicular to the direction in which each of the electrodes 210 and 220 extends. However, the present disclosure is not limited thereto, and the light emitting device 300 may be obliquely located without being perpendicular to the direction in which each of the electrodes 210 and 220 extends.

The display apparatus 10 may include the light emitting devices 300 emitting light in different wavelength ranges. The light emitting device 300 included in the first sub-pixel SPX1 may emit light of a first color having a first wavelength at a central wavelength band, the light emitting device 300 included in the second sub-pixel SPX2 may emit light of a second color having a second wavelength at a central wavelength band, and the light emitting device 300 included in the third sub-pixel SPX3 may emit light of a third color having a third wavelength at a central wavelength band. For example, the light of the first color may be blue light having a central wavelength band in a range of about 450 nm to about 495 nm, the light of the second color may be green light having a central wavelength band in a range of about 495 nm to about 570 nm, and the light of the third color may be red light having a central wavelength band in a range of about 620 nm to about 752 nm.

Thus, the light of the first color may be emitted from the first sub-pixel SPX1, the light of the second color may be emitted from the second sub-pixel SPX2, and the light of the third color may be emitted from the third sub-pixel SPX3. However, the present disclosure is not limited thereto, and in some cases, the first sub-pixel SPX1 , the second sub-pixel SPX2, and the third sub-pixel SPX3 may also include the light emitting devices 300 emitting light of the same color, thereby emitting light of substantially the same color.

A plurality of contact electrodes 260 may be located on the plurality of electrodes 210 and 220. The plurality of contact electrodes 260 may each have a shape extending in one direction. The plurality of contact electrodes 260 may be respectively in contact with the plurality of electrodes 210 and 220 and the light emitting devices 300, and the light emitting devices 300 may receive electrical signals from each of the first electrode 210 and the second electrode 220 through the contact electrodes 260.

The contact electrodes 260 may include a first contact electrode 261 and a second contact electrode 262. The first contact electrode 261 and the second contact electrode 262 may be located on the first electrode 210 and the second electrode 220, respectively. The first contact electrode 261 may be located on the first electrode 210, and the second contact electrode 262 may be located on the second electrode 220. The first contact electrode 261 and the second contact electrode 262 may each have a shape extending in the second direction DR2. The first contact electrode 261 and the second contact electrode 262 may be spaced apart from each other and face each other in the first direction DR1 and may form a stripe pattern in the light emitting area EMA of each sub-pixel SPXn.

In the drawing, it is illustrated that one first contact electrode 261 and one second contact electrode 262 are located in one sub-pixel SPXn, but the present disclosure is not limited thereto. The number of the first contact electrodes 261 and second contact electrodes 262 may vary depending on the number of the first electrodes 210 and second electrodes 220 located in each sub-pixel SPXn.

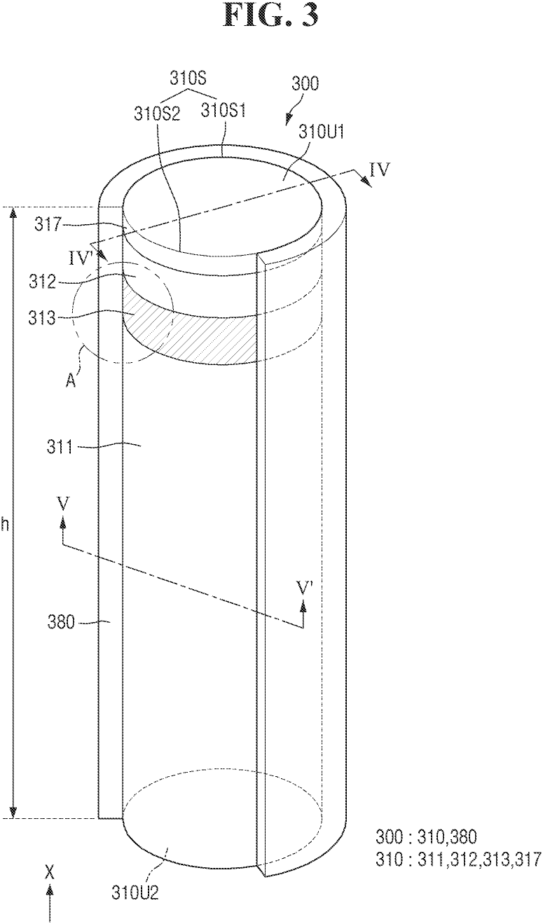

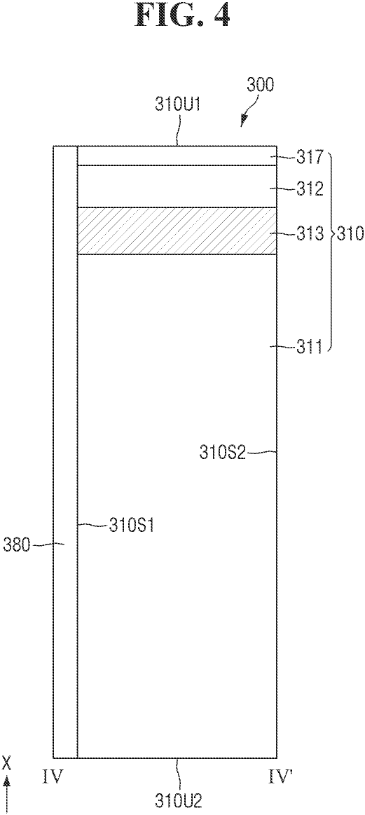

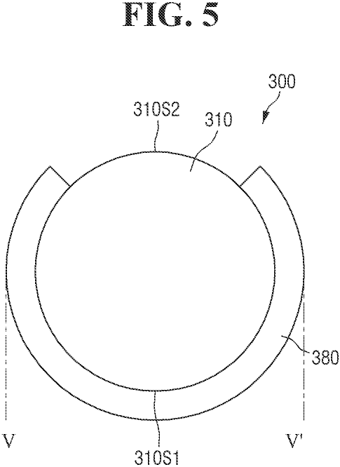

FIG. 3 is a schematic perspective view of the light emitting device according to one or more embodiments. FIG. 4 is a cross-sectional view of the light emitting device according to one or more embodiments, and is a cross-sectional view taken along the line IV-IV′ of FIG. 3. FIG. 5 is a cross-sectional view of the light emitting device according to one or more embodiments, and is a cross-sectional view taken along the line V-V′ of FIG. 3.

The light emitting device 300 may be a light emitting diode. For example, the light emitting device 300 may have a size of a micro-meter or nano-meter unit and may be an inorganic light emitting diode made of an inorganic material. The inorganic light emitting diode may be aligned between two electrodes in which a polarity is formed when forming an electric field in a corresponding direction between the two electrodes facing each other. The light emitting device 300 may be aligned between two electrodes due to the electric field formed on the two electrodes.

Referring to FIGS. 3 to 5, the light emitting device 300 includes a light emitting device core 310 and a transmission filter layer 380.

The light emitting device core 310 may have a shape extending in one direction X. The light emitting device core 310 may have a shape such as a rod, a wire, and a tube. In one or more embodiments, the light emitting device core 310 may have a cylindrical shape or a rod shape. However, the present disclosure is not limited thereto, and the light emitting device core 310 may have a shape of a cube, a rectangular parallelepiped, a polygonal pillar such as a hexagonal column, or the like, or have a shape that extends in one direction and has a partially inclined outer surface. A plurality of semiconductors included in the light emitting device core 310 according to one or more embodiments, which will be described below, may have a structure in which the plurality of semiconductors are sequentially located or stacked in the one direction X.

The light emitting device core 310 may include a semiconductor layer and an active layer doped with an arbitrary conductivity type (e.g., p-type or n-type) impurity. The semiconductor layer may receive an electrical signal applied from an external power source and may emit light in a corresponding wavelength range.

The light emitting device core 310 may include a first surface 310U1, a second surface 310U2, and a side surface 310S. The first surface 310U1 and the second surface 310U2 of the light emitting device core 310 may be surfaces respectively located on one side and the other side of the light emitting device core 310 in a length direction (e.g., extending direction, or direction X). That is, in the perspective view of the light emitting device 300 (see FIG. 3), the first surface 310U1 may be an upper surface of the light emitting device core 310 and the second surface 310U2 may be a lower surface of the light emitting device core 320.

The transmission filter layer 380 may be located on the side surface 310S of the light emitting device core 310. The transmission filter layer 380 may be located to partially surround the side surface 310S of the light emitting device core 310. The transmission filter layer 380 may be located to surround the side surface 310S of the light emitting device core 310 and may be located to expose at least partial area thereof. The transmission filter layer 380 may be located in direct contact with a partial area of the side surface 310S of the light emitting device core 310.

The transmission filter layer 380 may serve to control the transmission and reflection of light that is generated in the light emitting device core 310 and emitted through the side surface 310S of the light emitting device core 310. The transmission filter layer 380 may transmit at least a part of the light generated in the light emitting device core 310 and may reflect another part of the light according to an angle at which the light is incident on the transmission filter layer 380. For example, the transmission filter layer 380 may be a distributed Bragg reflector (DBR) layer. The transmission filter layer 380 will be described below in detail with reference to other drawings.

The side surface 310S of the light emitting device core 310 may include a first area 310S1 in which the transmission filter layer 380 is located and a second area 310S2 in which the transmission filter layer 380 is not located.

The first area 310S1 and the second area 310S2 may include a convex curved surface. In one or more embodiments, in a cross-section perpendicular to the extending direction X of the light emitting device core 310, an outer circumference of the first area 310S1 and an outer circumference of the second area 310S2 may respectively have a constant radius of curvature. In addition, the radius of curvature of the first area 310S1 and the radius of curvature of the second area 310S2 may be equal to each other. However, the present disclosure is not limited thereto, and the radius of curvature of the first area 310S1 of the light emitting device core 310 and the radius of curvature of the second area 310S2 thereof may be different from each other. The structure in which the first area 310S1 and the second area 310S2 have different radii of curvature is formed in a manufacturing process, and a detailed description thereof will be provided below with reference to other drawings.

The transmission filter layer 380 may be located to surround the first area 310S1 of the light emitting device core 310, and may be located such that one end and the other end thereof are positioned at boundaries between the first area 310S1 and the second area 310S2. One end and the other end of the transmission filter layer 380 may be parallel to each other. The second area 310S2 of the light emitting device core 310 may be exposed to the outside in a space in which one end and the other end of the transmission filter layer 380 are spaced apart from each other. The transmission filter layer 380 is located directly on the side surface 310S of the light emitting device core 310, and thus the surface of the light emitting device core 310, that is, the second area 310S2, may be directly exposed in the separated space. The second area 310S2 exposed to the outside by the transmission filter layer 380 may be one of light emitting surfaces through which light generated in the light emitting device core 310 is emitted.

Referring to FIG. 5, in a cross section of the light emitting device core 310, which is perpendicular to the one direction X that is the extending direction of the light emitting device 300, an outer circumferential length of the first area 310S1 may be greater than an outer circumferential length of the second area 310S2.

Referring to FIGS. 3 and 4, a maximum length h of the first area 310S1 in the one direction X may be equal to a length of the light emitting device core 310 in the one direction X. In addition, the maximum length h of the first area 310S1 in the one direction X may be equal to the maximum length h of the second area 310S2 in the one direction X. That is, one end and the other end of the transmission filter layer 380 may be located to be symmetrical to each other as shown in FIGS. 3 and 5. That is, the lengths h of the transmission filter layer 380, which are positioned at the boundaries between the first area 310S1 and the second area 310S2, in the one direction X may be substantially the same. Thus, an area of the first area 310S1 may be greater than an area of the second area 310S2.

Hereinafter, a structure of the light emitting device core 310 will be described with reference to FIGS. 3 and 4.

Referring to FIGS. 3 and 4, the light emitting device core 310 includes a first semiconductor layer 311, a second semiconductor layer 312, and an active layer 313. The light emitting device core 310 may further include at least one electrode layer 317. In FIG. 3, it is illustrated that the light emitting device core 310 includes one electrode layer 317, but the present disclosure is not limited thereto, and the light emitting device core 310 may include a larger number of electrode layers.

The first semiconductor layer 311, the active layer 313, the second semiconductor layer 312, and the electrode layer 317 may be located by being sequentially stacked in the one direction X, which is the extending direction of the light emitting device core 310. Hereinafter, for convenience of description, in describing the structure of the light emitting device 300, an upper portion or an upper side refers to one side (an upper side in the drawing) of the one direction X, which is the extending direction of the light emitting device core 310, and similarly, an upper surface denotes a surface facing one side of the one direction X. In addition, a lower portion or a lower side refers to the other side of the one direction X, which is the extending direction of the light emitting device core 310, and similarly, a lower surface denotes a surface facing the other side of the one direction X.

For example, the first semiconductor layer 311 may be an n-type semiconductor having a first conductive type. As an example, when the light emitting device core 310 emits light in a blue wavelength range, the first semiconductor layer 311 may include a semiconductor material having a chemical formula of AlₓGa_{y}ln1_{-x-y}N (0 <= x <= 1, 0 <= y <=1, and 0 <= x + y <= 1). For example, the semiconductor material may be one or more of n-type doped AlGalnN, GaN, AlGaN, InGaN, AIN, and InN. The first semiconductor layer 311 may be doped with a first conductive type dopant. As an example, the first conductive type dopant may be silicon (Si), germanium (Ge), Tin (Sn), or the like. In one or more embodiments, the first semiconductor layer 311 may include n-GaN doped with n-type Si. The first semiconductor layer 311 may have a length ranging from about 1.5 µm to about 5 µm, but the present disclosure is not limited thereto.

The second semiconductor layer 312 is located on the active layer 313 to be described below. For example, the second semiconductor layer 312 may be a p-type semiconductor having a second conductive type. As an example, when the light emitting device core 310 emits light in a blue or green wavelength range, the second semiconductor layer 312 may include a semiconductor material having a chemical formula of AlₓGa_{y}ln1_{-x-y}N (0 <= x <= 1, 0 <= y <= 1, and 0 <= x + y <= 1). For example, the semiconductor material may be one or more of p-type doped AlGalnN, GaN, AlGaN, InGaN, AlN, and InN. The second semiconductor layer 312 may be doped with a second conductive type dopant. As an example, the second conductive type dopant may be magnesium (Mg), zinc (Zn), calcium (Ca), selenium (Se), barium (Ba), or the like. In one or more embodiments, the second semiconductor layer 312 may include p-GaN doped with p-type Mg. The second semiconductor layer 312 may have a length ranging from about 0.05 µm to about 0.10 µm, but the present disclosure is not limited thereto.

Meanwhile, in the drawing, the first semiconductor layer 311 and the second semiconductor layer 312 are illustrated as being formed as one layer, but the present disclosure is not limited thereto. In some cases, depending on the material included in the active layer 313, the first semiconductor layer 311 and the second semiconductor layer 312 may further include a larger number of layers, for example, a clad layer or a tensile strain barrier reducing (TSBR) layer.

The active layer 313 is located between the first semiconductor layer 311 and the second semiconductor layer 312. The active layer 313 may include a material having a single or multiple-quantum-well structure. When the active layer 313 includes a material having a multiple-quantum-well structure, the active layer 313 may have a structure in which quantum layers and well layers are alternately stacked. The active layer 313 may emit light due to a combination of electron-hole pairs in response to electrical signals applied through the first semiconductor layer 311 and the second semiconductor layer 312. As an example, when the active layer 313 emits the light in the blue wavelength range, the active layer 313 may include a material such as AlGaN and AlGalnN. For example, when the active layer 313 has a multiple-quantum-well structure in which quantum layers and well layers are alternately stacked, the quantum layer may include a material such as AlGaN or AlGalnN, and the well layer may include a material such as GaN or AllnN. In one or more embodiments, the active layer 313 includes AlGalnN as the quantum layer and AllnN as the well layer. As described above, the active layer 313 may emit blue light having a central wavelength band in a range of about 450 nm to about 495 nm.

However, the present disclosure is not limited thereto, and the active layer 313 may have a structure in which semiconductor materials with high bandgap energy and semiconductor materials with low bandgap energy are alternately stacked or may include other Group III to Group V semiconductor materials according to a wavelength range of light being emitted. The light emitted by the active layer 313 is not limited to the light in the blue wavelength range, and in some cases, the active layer 313 may emit light in the wavelength range of red or green. A length of the active layer 313 may range from about 0.05 µm to about 0.10 µm, but the present disclosure is not limited thereto.

The electrode layer 317 may be an ohmic contact electrode. However, the present disclosure is not limited thereto, and the electrode layer 317 may also be a Schottky contact electrode. The electrode layer 317 may include a conductive metal. For example, the electrode layer 317 may include at least one among aluminum (Al), titanium (Ti), indium (In), gold (Au), silver (Ag), indium tin oxide (ITO), indium zinc oxide (IZO), and indium tin-zinc oxide (ITZO). In addition, the electrode layer 317 may include a semiconductor material doped with an n-type or p-type impurity. The electrode layers 317 may include the same material or different materials, but the present disclosure is not limited thereto.

In one or more embodiments, the first surface 310U1 of the light emitting device core 310, that is, the upper surface of the light emitting device core 310, may be an upper surface of the electrode layer 317. In addition, the second surface 310U2 of the light emitting device core 310, that is, the lower surface of the light emitting device core 310, may be a lower surface of the first semiconductor layer 311.

The second area 310S2 of the light emitting device core 310 may include at least a part of a side surface of the active layer 313.

The transmission filter layer 380 may be located to surround a part of a side surface of each of the first semiconductor layer 311, the second semiconductor layer 312, the active layer 313, and the electrode layer 317. The transmission filter layer 380 may be located directly on the side surface of each of the first semiconductor layer 311, the second semiconductor layer 312, the active layer 313, and the electrode layer 317. The transmission filter layer 380 may extend in the length direction of the light emitting device core 310 and may be formed to cover from the first semiconductor layer 311 to the electrode layer 317 in the first area 310S1.

The transmission filter layer 380 may be located on the side surface 310S of the light emitting device core 310 and may be located to expose the side surface of each of the first semiconductor layer 311, the second semiconductor layer 312, the active layer 313, and the electrode layer 317 located in the second area 310S2 of the light emitting device core 310. The transmission filter layer 380 may extend in the length direction of the light emitting device core 310 and may be formed to expose from the first semiconductor layer 311 to the electrode layer 317 in the second area 310S2.

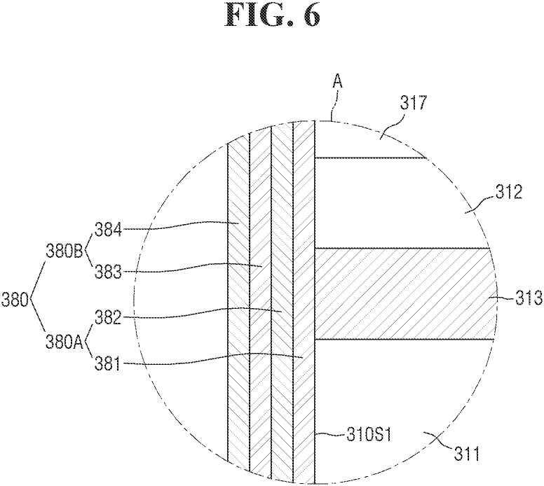

FIG. 6 is an enlarged cross-sectional view of portion A of FIG. 3.

Referring to FIG. 6, as described above, the transmission filter layer 380 may be a DBR layer. The transmission filter layer 380 may have a structure in which optical layers including a plurality of inorganic films having different refractive indexes are repeatedly stacked.

The transmission filter layer 380 may include one or more optical layers 380A and 380B in which a plurality of inorganic films 381, 382, 383, and 384 having different refractive indexes are stacked. In one or more embodiments, the transmission filter layer 380 may include a first optical layer 380A and a second optical layer 380B.

The first optical layer 380A and the second optical layer 380B may be located in the first area 310S1 of the light emitting device core 310. The first optical layer 380A and the second optical layer 380B may be sequentially stacked in a direction perpendicular to the one direction X, which is the extending direction of the light emitting device core 310, in the first area 310S1 of the light emitting device core 310. That is, the first optical layer 380A and the second optical layer 380B may be located on the light emitting device core 310 by being sequentially stacked in an outward direction of the light emitting device core 310.

The first optical layer 380A may include a first inorganic film 381 having a first refractive index 1N, and a second inorganic film 382 having a second refractive index 2N that is different from the first refractive index n1. The first inorganic film 381 and the second inorganic film 382 may be sequentially stacked in a direction perpendicular to the one direction X. The first refractive index n1 may be less than the second refractive index n2. That is, each of the refractive indexes of the first inorganic film 381 and the second inorganic film 382, which are sequentially stacked in the outward direction of the light emitting device core 310 with respect to the light emitting device core 310, may have a relation of n1 <n2 (where n1 is the refractive index of the first inorganic film 381, and n2 is the refractive index of the second inorganic film 382).

The second optical layer 380B may include a third inorganic film 383 having the first refractive index n1, and a fourth inorganic film 384 having the second refractive index n2 that is different from the first refractive index. The third inorganic film 383 and the fourth inorganic film 384 may be sequentially stacked in the direction perpendicular to the one direction X.

That is, the transmission filter layer 380 may have a structure in which the first inorganic film 381 having the first refractive index n1, and the second inorganic film 382 having the second refractive index n2 that is different from the first refractive index n1 are alternately and repeatedly stacked.

In the drawing, the transmission filter layer 380 including the first to fourth inorganic films 381 to 384, that is, the transmission filter layer 380 including two pairs of optical layers 380A and 380B, is illustrated as an example, but the present disclosure is not limited thereto. For example, the transmission filter layer 380 may include more pairs of optical layers, or three or more inorganic films having different respective refractive indexes may be stacked to form a pair of optical layers.

The plurality of inorganic films 381, 382, 383, and 384 included in the transmission filter layer 380 may each include a transparent insulating material. For example, the transparent insulating material may include silicon oxide (SiOₓ), silicon nitride (SiNₓ), silicon oxynitride (SiOₓN_{y}), titanium oxide (TiOx), or the like. Thus, the transmission filter layer 380 may also serve to protect and insulate the light emitting device core 310.

The transmission filter layer 380 may transmit a part of light, which is generated inside the light emitting device core 310 and incident on the transmission filter layer 380, and reflect the remaining part thereof. In the transmission filter layer 380, two inorganic films 381 and 382 having different refractive indexes are alternately stacked so that a difference in refractive index is repeatedly formed, and thus the light incident on the transmission filter layer 380 may have different transmittance according to an incident angle thereof. That is, by controlling the material included in each of the inorganic films 381 and 382 to be stacked, the thickness of each of the inorganic films 381 and 382, and/or the number of the inorganic films 381 and 382, the reflectance may be controlled according to an angle at which light is incident on the transmission filter layer 380.

For example, in order to optimally increase the reflectance of light incident on the transmission filter layer 380, the thickness of each of the inorganic films 381, 382, 383, and 384 may be controlled according to the wavelength and refractive index of the light. In a case in which a refractive index of a stacked refractive layer (inorganic film) is n and a wavelength of light to be reflected is λ₁, the light in the corresponding wavelength range of λ₁ can be effectively reflected when low refractive layers and high refractive layers each having a thickness of (λ₁)/(4xn) are alternately stacked.

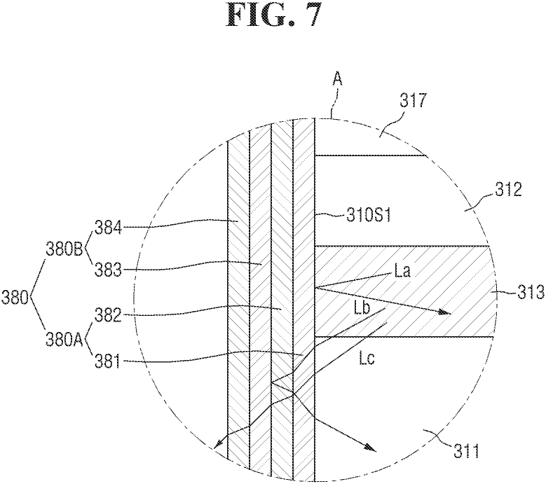

FIG. 7 is a schematic view illustrating a traveling direction of light generated in the light emitting device according to one or more embodiments.

Light L (e.g., partial lights La, Lb, and Lc) emitted from the active layer 313 of the light emitting device core 310 may travel in a random direction without directionality. The light L emitted from the active layer 313 of the light emitting device core 310 may travel toward the side surface 310S as well as the first surface 310U1 and the second surface 310U2 of the light emitting device core 310. The traveling direction of the light L generated in and emitted from the active layer 313 is not limited in directionality.

In FIG. 7, the traveling direction of the light L, which is generated in the active layer 313 and travels toward the first area 310S1 of the light emitting device core 310, that is, toward the transmission filter layer 380, is schematically illustrated.

Partial light La of the light L that travels toward the transmission filter layer 380 may be incident on one surface of the first inorganic film 381. A part of the light La incident on one surface of the first inorganic film 381 may be reflected from the first inorganic film 381 according to an incident angle and may travel toward the inside of the light emitting device core 310.

Further, another partial light Lb of the light L that travels toward the transmission filter layer 380 may travel toward the first inorganic film 381 to be transmitted through the first inorganic film 381 and the second inorganic film 382, and may be incident on one surface of the third inorganic film 383. Because the refractive index n1 of the third inorganic film 383 is less than the refractive index n2 of the second inorganic film 382, the light Lb incident on one surface of the third inorganic film 383 may be totally reflected from one surface of the third inorganic film 383 due to a difference in refractive index and may travel toward the inside of the light emitting device core 310.

Still another partial light Lc of the light L that travels toward the transmission filter layer 380 may travel toward the first inorganic film 381 to be transmitted through the first to fourth inorganic films 381 to 384 according to an incident angle and may be emitted to the outside of the light emitting device 300.

According to an angle at which the light L, which is generated in and emitted from the active layer 313, is incident on one surface of the transmission filter layer 380, a part of the light L may be reflected from the one surface and may travel to the inside of the light emitting device core 310, and another part thereof may be transmitted through the light emitting device core 310 and emitted to the outside of the light emitting device 300. However, by stacking a plurality of inorganic films having different refractive indexes, most of the light L incident on the transmission filter layer 380 may travel toward the inside of the light emitting device core 310.

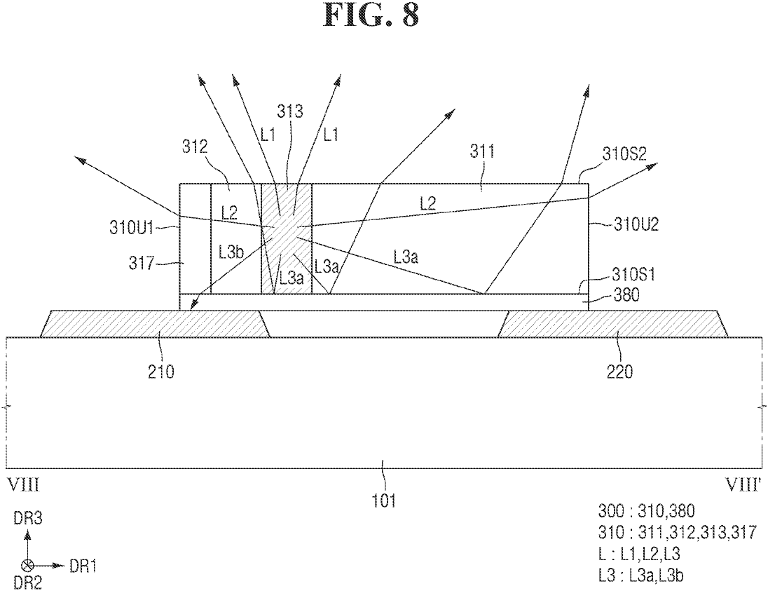

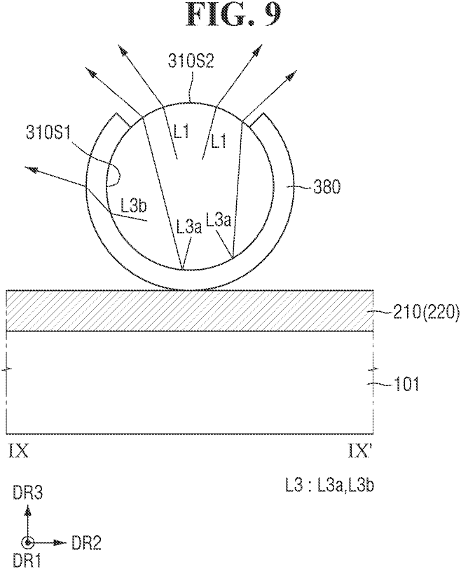

FIG. 8 is a schematic cross-sectional view taken along the line VIII-VIII′ of FIG. 2. FIG. 9 is a schematic cross-sectional view taken along the line IX-IX′ of FIG. 2. Referring to FIGS. 8 and 9, the traveling direction of the light L emitted from the light emitting device 300, which is located on the first electrode 210 and the second electrode 220, will be described.

Referring to FIGS. 8 and 9, the display apparatus 1 may further include a substrate 101. The first electrode 210 and the second electrode 220 may be located on the substrate 101. As described above, one end portion and the other end portion of the light emitting device 300 may be located on the first electrode 210 and the second electrode 220, respectively. FIGS. 8 and 9 illustrate that the light emitting device 300 is directly located on the first electrode 210 and the second electrode 220, but are only conceptual views, and the light emitting device 300 may be electrically connected to each of the first electrode 210 and the second electrode 220.

The light emitting device 300 may be located on the substrate 101. The light emitting device 300 may be located on the substrate 101 such that an upper surface of the substrate 101 and the extending direction (the direction X in FIG. 4) of the light emitting device 300 are parallel to each other. That is, the light emitting device 300 may be located such that the side surface 310S of the light emitting device core 310 faces the upper surface of the substrate 101.

The light emitting device 300 may be located such that the second area 310S2 of the light emitting device core 310 faces upward. In addition, the light emitting device 300 may be located such that the first area 310S1 of the light emitting device core 310 faces downward. The first area 310S1 of the light emitting device core 310 may be located on a side of the substrate 101. The transmission filter layer 380 may be located between the light emitting device core 310 and the substrate 101.

The light L, which is generated in the active layer 313 of the light emitting device core 310, may include first light L1, second light L2, and third light L3 according to the traveling direction thereof.

The first light L1 may be light traveling toward the second area 310S2 of the light emitting device core 310. The second light L2 may be light directed toward the first surface 310U1 and/or the second surface 310U2 of the light emitting device core 310. The third light L3 may be light traveling toward the first area 310S1 of the light emitting device core 310.

The first light L1 may be transmitted through the second area 310S2 of the light emitting device core 310 to be emitted to the outside of the light emitting device 300. The first light L1 may be emitted in an upward direction DR3 with respect to the substrate 101.

The second light L2 may be transmitted through the first surface 310U1 and the second surface 310U2 of the light emitting device core 310 to be emitted to the outside of the light emitting device 300. The second light L2 may be emitted in the display direction DR3 of the display apparatus 1.

The third light L3 may travel toward the transmission filter layer 380 located in the first area 310S1 of the light emitting device core 310. Partial light L3a of the third light L3 that travels toward the transmission filter layer 380 may be reflected from the transmission filter layer 380 at an interface surface of the first area 310S1 of the light emitting device core 310 and may travel toward the first area 310S1 or the first surface 310U1 and the second surface 310U2 of the light emitting device core 310 to be emitted to the outside of the light emitting device 300. Accordingly, the partial light L3a of the third light L3 that travels toward and is reflected from the transmission filter layer 380 may be emitted in the upward direction with respect to the substrate 101. In addition, partial light L3b of the third light L3 that travels toward the transmission filter layer 380 may be transmitted through the transmission filter layer 380 to be emitted to the outside of the light emitting device 300. Accordingly, the third light L3b that travels toward and is transmitted through the transmission filter layer 380 may be emitted in a downward direction with respect to the substrate 101. However, most of the third light L3 that travels toward the transmission filter layer 380 may be reflected to be emitted in the upward direction with respect to the substrate 101.

In one or more embodiments, the first surface 310U1, the second surface 310U2, and the second area 310S2 of the light emitting device core 310 may be light emitting surfaces through which the light L generated in the light emitting device core 310 is emitted to the outside of the light emitting device 300. When the light L generated in the light emitting device core 310 is incident toward the first area 310S1 of the light emitting device core 310, most of the light incident toward the first area 310S1 of the light emitting device core 310 may be reflected from the transmission filter layer 380 so that a travel path of the light may be changed. Thus, the light may be emitted to the outside through the first surface 310U1, the second surface 310U2, and the second area 310S2 of the light emitting device core 310.

Accordingly, the light emitting device 300 according to one or more embodiments may control the traveling direction of the light L, which is generated in the active layer 313 and randomly travels without directionality by placing the transmission filter layer 380 on the outer surface of the light emitting device core 310. For example, by placing the transmission filter layer 380 in a direction opposite to the display direction DR3 of the display apparatus 10, the third light L3, which is emitted from the active layer 313 and travels in the downward direction with respect to the substrate 101, is allowed to travel in the upward direction with respect to the substrate 101, so that the loss of light may be reduced or minimized, thereby improving light emitting efficiency of the display apparatus 10.

Hereinafter, a manufacturing method of the light emitting device 300 according to one or more embodiments will be described in detail with reference to other drawings.

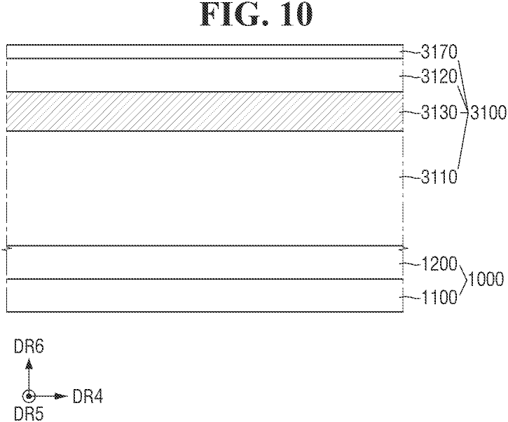

FIGS. 10 to 17 are cross-sectional views illustrating the manufacturing process of the light emitting device according to one or more embodiments.

In FIGS. 10 to 17, a fourth direction DR4, a fifth direction DR5, and a sixth direction DR6 are defined. The fourth direction DR4 and the fifth direction DR5 may be directions perpendicular to each other in one plane. The sixth direction DR6 may be a direction perpendicular to a plane in which the fourth direction DR4 and the fifth direction DR5 are positioned. The sixth direction DR6 is perpendicular to each of the fourth direction DR4 and the fifth direction DR5. In FIGS. 10 to 17, the sixth direction DR6 may be a direction in which a plurality of material layers included in a core structure 3100, which will be described below, are stacked.

First, referring to FIG. 10, the core structure 3100 is formed on a lower substrate 1000.

The lower substrate 1000 including a base substrate 1100 and a buffer material layer 1200 formed on the base substrate 1100 is prepared. The base substrate 1100 may include a sapphire (Al₂O₃) substrate and a transparent substrate such as glass. However, the present disclosure is not limited thereto, and the base substrate 1100 may be formed as a conductive substrate such as a GaN, SiC, ZnO, Si, GaP, or GaAs substrate. Hereinafter, a case in which the base substrate 1100 is a sapphire (Al₂O₃) substrate will be described as an example.

A plurality of semiconductor layers are formed on the base substrate 1100. The plurality of semiconductor layers grown by an epitaxial method may be formed by growing a seed crystal. Here, the method of forming the semiconductor layers may include an electron beam deposition method, a physical vapor deposition (PVD) method, a chemical vapor deposition (CVD) method, a plasma laser deposition (PLD) method, a dual-type thermal evaporation method, a sputtering method, a metal-organic chemical vapor deposition method (MOCVD), or the like, and for example, the MOCVD method. However, the present disclosure is not limited thereto.

A precursor material for forming the plurality of semiconductor layers is not particularly limited within a range that can be normally selected to form a target material. As an example, the precursor material may be a metal precursor including an alkyl group such as a methyl group or an ethyl group. For example, the precursor material may be a compound such as trimethyl gallium (Ga(CH₃)₃), trimethyl aluminum (Al(CH₃)₃), or triethyl phosphate ((C₂H₅)₃PO₄), but the present disclosure is not limited thereto. Hereinafter, a method of forming the plurality of semiconductor layers, process conditions, and the like will be omitted in the description, and a sequence of the manufacturing method and a stacked structure of the light emitting device 300 will be described in detail.

The buffer material layer 1200 may be formed on the base substrate 1100. In the drawing, it is illustrated that one buffer material layer 1200 is stacked, but the present disclosure is not limited thereto, and a plurality of buffer layers may be formed. The buffer material layer 1200 may be located to reduce a lattice constant difference between a first semiconductor 3110 and the base substrate 1100.

Subsequently, the core structure 3100 is formed on the lower substrate 1000. The core structure 3100 may include the first semiconductor 3110, a device active material layer 3130, a second semiconductor 3120, and an electrode material layer 3170. The plurality of material layers included in the core structure 3100 may be formed by performing typical processes as described above, and the plurality of layers included in the core structure 3100 may correspond to the respective layers included in the light emitting device core 310 of the light emitting device 300 according to one or more embodiments. That is, the first semiconductor 3110, the device active material layer 3130, the second semiconductor 3120, and the electrode material layer 3170 may include the same materials as the first semiconductor layer 311, the active layer 313, the second semiconductor layer 312, and the electrode layer 317 of the light emitting device core 310, respectively.

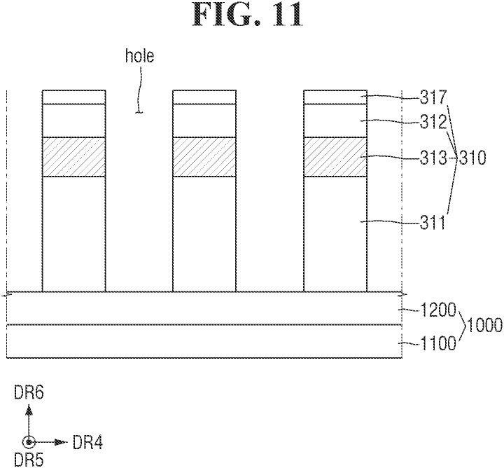

Next, referring to FIG. 11, the core structure 3100 is etched in a vertical direction (or in the sixth direction DR6) to form light emitting device cores 310 spaced apart from each other. The vertical direction in which the core structure 3100 is etched may be parallel to a stacked direction of the plurality of material layers included in the core structure 3100. The core structure 3100 may be etched by a typical method. For example, the core structure 3100 may be etched by a method of forming an etch mask layer thereon and etching the core structure 3100 in a direction perpendicular to the lower substrate 1000 along the etch mask layer. A separated space (hole) may be formed between the light emitting device cores 310 by the above etching process.

For example, the process of etching the core structure 3100 may be performed through a dry etching method, a wet etching method, a reactive ion etching (RIE) method, an inductively coupled plasma reactive ion etching (ICP-RIE) method, or the like. In the case of dry etching, anisotropic etching may be possible, and thus, the dry etching method may be suitable for vertical etching. When the above-described etching method is used, an etchant may be chlorine (Cl₂), oxygen (O₂), or the like. However, the present disclosure is not limited thereto.

In some embodiments, the core structure 3100 may be etched by mixing the dry etching method and the wet etching method. For example, first, etching in a depth direction may be performed by the dry etching method, and then a sidewall etched through the wet etching method, which is an isotropic etching method, may be placed on a plane perpendicular to the surface.

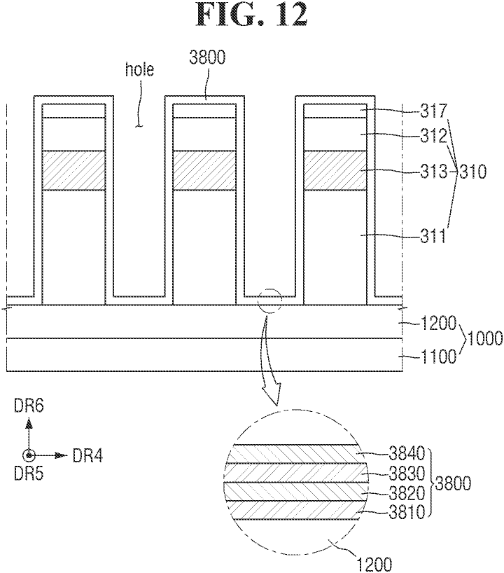

Subsequently, referring to FIG. 12, a transmission filter material layer 3800 is formed entirely on the light emitting device cores 310. The transmission filter material layer 3800 may be formed on side and upper surfaces of each of the light emitting device cores 310, and may also be formed on the buffer material layer 1200 exposed in an area in which the light emitting device cores 310 are spaced apart from each other.

The transmission filter material layer 3800 may be formed using a method of applying or immersing an inorganic material on an outer surface of the light emitting device core 310. However, the present disclosure is not limited thereto. As an example, the transmission filter material layer 3800 may be formed by atomic layer deposition (ALD).

The transmission filter material layer 3800 may include a plurality of stacked inorganic material layers. The transmission filter material layer 3800 may include a first inorganic material layer 3810, a second inorganic material layer 3820, a third inorganic material layer 3830, and a fourth inorganic material layer 3840.

The first inorganic material layer 3810 and the third inorganic material layer 3830 may include a material having the same refractive index. The refractive index of the material included in the first inorganic material layer 3810 and the third inorganic material layer 3830 may be a first refractive index n1. The second inorganic material layer 3820 and the fourth inorganic material layer 3840 may include a material having the same refractive index. The refractive index of the material included in the second inorganic material layer 3820 and the fourth inorganic material layer 3840 may be a second refractive index n2 different from the first refractive index n1. The first refractive index n1 may be less than the second refractive index n2.

The plurality of inorganic material layers 3810, 3820, 3830, and 3840 included in the transmission filter material layer 3800 may be sequentially stacked by a typical process. The plurality of layers included in the plurality of inorganic material layers 3810, 3820, 3830, and 3840 included in the transmission filter material layer 3800 may correspond to the respective layers included in the transmission filter layer 380 of the light emitting device 300 according to one or more embodiments shown in FIG. 6. That is, the first inorganic material layer 3810, the second inorganic material layer 3820, the third inorganic material layer 3830, and the fourth inorganic material layer 3840 of the transmission filter material layer 3800 may include the same materials as the first inorganic film 381, the second inorganic film 382, the third inorganic film 383, and the fourth inorganic film 384 of the transmission filter layer 380, respectively.

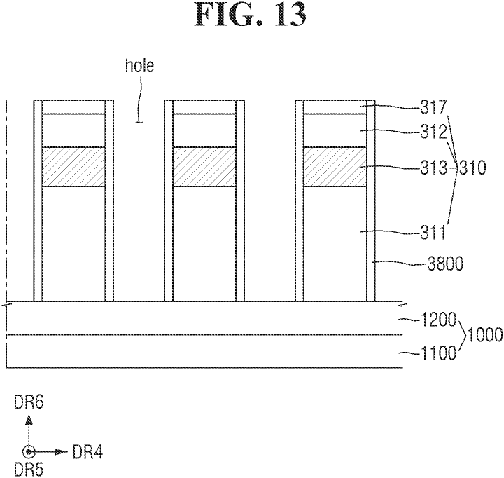

Subsequently, referring to FIG. 13, a part of the transmission filter material layer 3800 may be partially removed such that the transmission filter material layer 3800 exposes an upper surface of the light emitting device core 310 but surrounds the side surface of the light emitting device core 310. For example, in the process, the transmission filter material layer 3800 may be partially removed to expose the upper surface of the electrode layer 317 of the light emitting device core 310. The process of partially removing the transmission filter material layer 3800 may be performed by a process such as dry etching, etch-back, or the like, which is anisotropic etching. In the process of partially removing the transmission filter material layer 3800, the transmission filter material layer 3800 located on the buffer material layer 1200, which is exposed in the area in which the light emitting device cores 310 are spaced apart from each other, may also be partially removed.

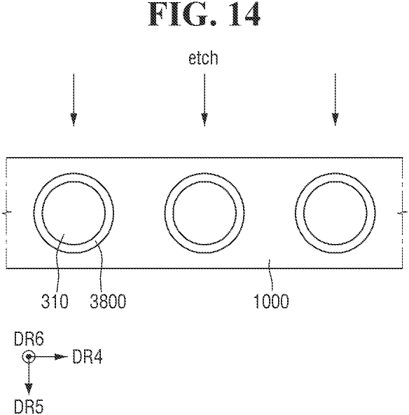

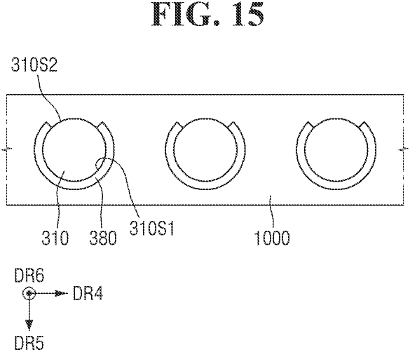

Next, referring to FIGS. 14 and 15, a partial area of the transmission filter material layer 3800 that entirely covers the side surface of the light emitting device core 310 is removed to form the transmission filter layer 380 that exposes a partial area of the light emitting device core 310 to the outside.

The process of forming the transmission filter layer 380 by removing a partial area of the transmission filter material layer 3800 may be performed by etching in a direction perpendicular to a stacking direction DR6 of the plurality of layers included in the light emitting device core 310. The direction in which the transmission filter material layer 3800 is etched may be a direction DR5 perpendicular to the stacking direction DR6 of the plurality of layers included in the light emitting device core 310. The transmission filter material layer 3800 may be etched by a typical method. For example, the etching process of removing a part of the transmission filter material layer 3800 may be performed by a process such as etch-back or the like.

By the above etching process, at least a part of the transmission filter material layer 3800 located in the fifth direction DR5 may be removed. Accordingly, as the transmission filter material layer 3800 is removed, the side surface of the light emitting device core 310 may be divided into the first area 310S1 and the second area 310S2.

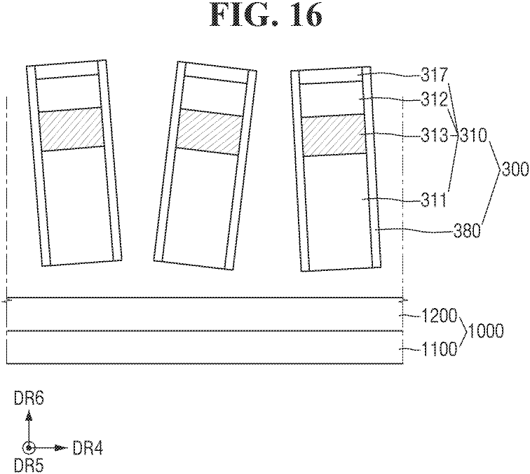

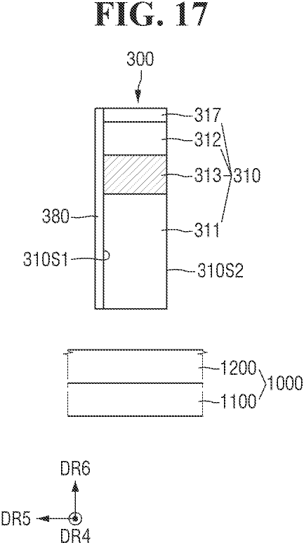

Next, referring to FIGS. 16 and 17, a structure fixed to the lower substrate 1000 and including the light emitting device core 310 and the transmission filter layer 380 is separated from the lower substrate 1000. The structure may include the light emitting device core 310 and the transmission filter layer 380 surrounding the first area 310S1 of the light emitting device core 310. By separating the structure including the light emitting device core 310 and the transmission filter layer 380 from the lower substrate 1000, the light emitting device 300 according to one or more embodiments may be manufactured. The method of separating the structure including the light emitting device core 310 and the transmission filter layer 380 from the lower substrate 1000 is not particularly limited. The process of separating the structure including the light emitting device core 310 and the transmission filter layer 380 from the lower substrate 1000 may be performed by a physical separation method, a chemical separation method, or the like.

The light emitting device 300 manufactured by the manufacturing method of the light emitting device 300 according to one or more embodiments may have a structure in which the transmission filter layer 380 is not located in at least a partial area of the side surface of the light emitting device core 310. That is, the side surface of the light emitting device core 310 may include the first area 310S1 in which the transmission filter layer 380 is located and the second area 310S2 in which the transmission filter layer 380 is not located. Light generated in the light emitting device core 310 may be emitted through the second area 310S2, the first surface 310U1, and the second surface 310U2 of the light emitting device core 310. By selectively placing the transmission filter layer 380 on a partial area of the side surface of the light emitting device core 310 through an etching process, it is possible to increase the amount of light emitted to the display surface of the display apparatus 10 by controlling the arrangement and area of the surface through which the light emitted from the light emitting device 300 is emitted.

Hereinafter, other embodiments will be described. In the following embodiments, descriptions of components which are the same as those described above may be omitted or simplified, and differences from previous embodiments will be mainly described.

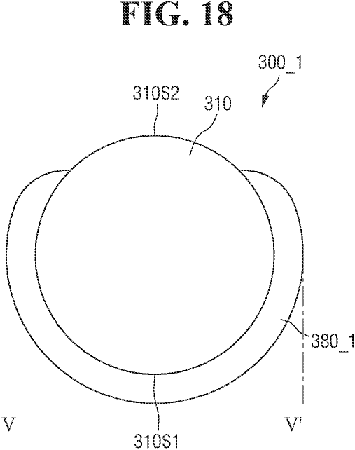

FIG. 18 is a cross-sectional view illustrating another example of the light emitting device taken along the line V-V′ of FIG. 3.

Referring to FIG. 18, a difference from one or more embodiments of FIG. 5 is that, in a light emitting device 300_1 according to one or more embodiments, a thickness of a transmission filter layer 380_1 is different for some respective areas.

For example, the transmission filter layer 380_1 located in a first area 310S1 of the light emitting device core 310 may have substantially the same thickness. The thickness of the transmission filter layer 380__1 may decrease from the first area 310S1 toward a second area 310S2 in an area adjacent to the second area 310S2 of the light emitting device core 310. Such a thickness may be formed because an etching rate is different for each inorganic material layer constituting each transmission filter material layer 3800 in an etching process of removing the transmission filter material layer 3800. In addition, the light emitting device 300_1 having a cross-sectional structure shown in FIG. 18 may be formed as a time during which an etching solution is in contact with a surface located on an upper portion is longer than a time during which the etching solution is in contact with a surface located on a lower portion in the etching process of removing the transmission filter material layer 3800.

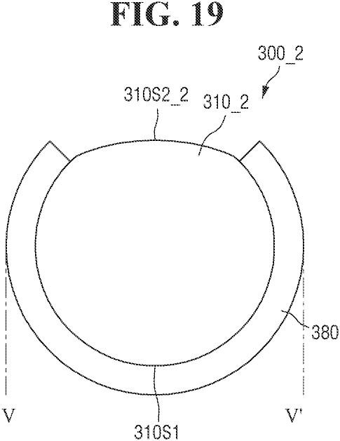

FIG. 19 is a cross-sectional view illustrating still another example of the light emitting device taken along the line V-V′ of FIG. 3.

Referring to FIG. 19, a difference from one or more embodiments of FIG. 5 is that, in a light emitting device 300_2 according to one or more embodiments, a radius of curvature of a first area 310S1 of a light emitting device core 310_2 and a radius of curvature of a second area 310S2_2 are different.

For example, in a cross section of the light emitting device core 310_2 taken in a direction perpendicular to an extending direction of the light emitting device core 310_2, the first area 310S1 has a first radius of curvature and the second area 310S2_2 has a second radius of curvature that is greater than the first radius of curvature. The above structure of the light emitting device 300_2 may be formed in an etching process of removing a transmission filter material layer 3800. For example, the light emitting device 300_2 having the cross-sectional structure shown in FIG. 19 may be formed by partially etching the second area 310S2_2 of the light emitting device core 310_2, which is exposed to an etching solution, by the etching solution.

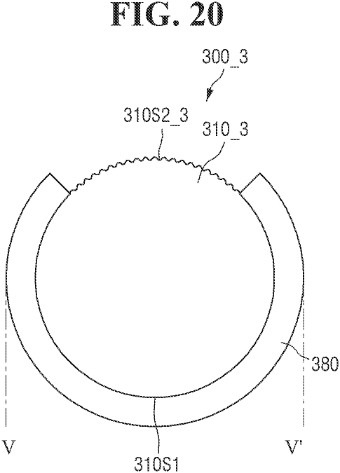

FIG. 20 is a cross-sectional view illustrating yet another example of the light emitting device taken along the line V-V′ of FIG. 3.

Referring to FIG. 20, a difference from one or more embodiments of FIG. 5 is that, in a light emitting device 300_3 according to one or more embodiments, a surface roughness (or surface unevenness) is formed in a second area 310S2_3 of a light emitting device core 310_3.

For example, the second area 310S2_3 of the light emitting device core 310_3 may include a surface roughness. The above structure of the light emitting device 300_3 may be formed in an etching process of removing a transmission filter material layer 3800. For example, the second area 310S2_3 of the light emitting device core 310_3, which is exposed to an etching solution, may include a surface roughness due to the etching solution. Due to the uneven roughness included in the second area 310S2_3 of the light emitting device core 310_3, light emitted through the second area 310S2_3 of the light emitting device core 310_3 may travel in various directions.

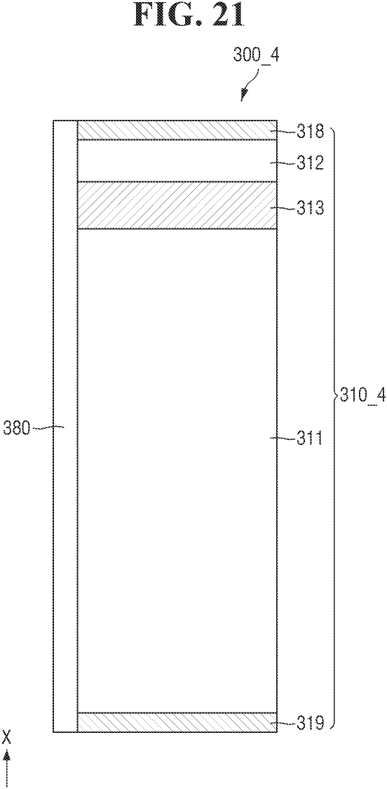

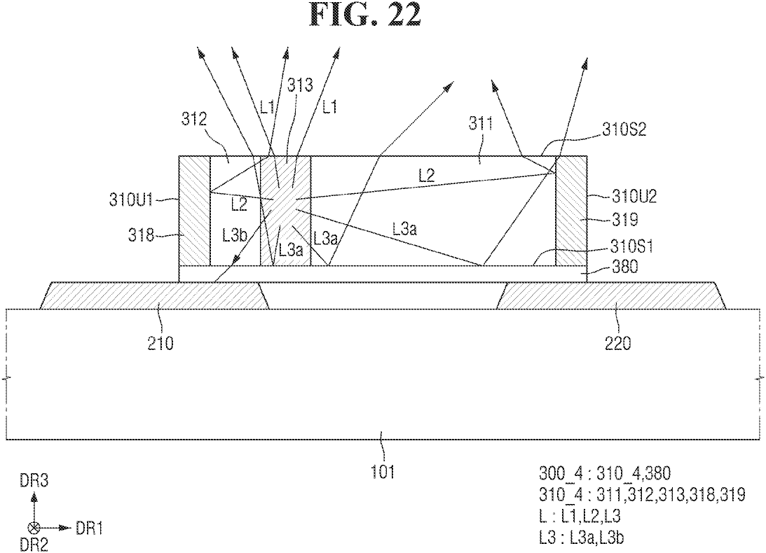

FIG. 21 is a cross-sectional view of a light emitting device according to one or more other embodiments. FIG. 22 is a schematic cross-sectional view illustrating that the light emitting device of FIG. 21 is located on electrodes. Referring to FIGS. 21 and 22, a light emitting device 300_4 according to one or more embodiments is different from the light emitting device 300 of FIG. 4 in that the light emitting device 300_4 includes a plurality of electrode layers 318 and 319.

Referring to FIGS. 21 and 22, a light emitting device core 310_4 of the light emitting device 300_4 according to one or more embodiments may include the plurality of electrode layers 318 and 319.

The plurality of electrode layers 318 and 319 may be ohmic contact electrodes. However, the present disclosure is not limited thereto, and the plurality of electrode layers 318 and 319 may be Schottky contact electrodes.

The plurality of electrode layers 318 and 319 may include a first electrode layer 318 and a second electrode layer 319. The first electrode layer 318 may be located on an upper surface of a second semiconductor layer 312, and the second electrode layer 319 may be located on a lower surface of a first semiconductor layer 311.

When the light emitting device 300 is electrically connected to the electrode or the contact electrode, the first electrode layer 318 and the second electrode layer 319 may reduce resistance between the light emitting device 300 and the electrode or between the light emitting device 300 and the contact electrode. The first electrode layer 318 and the second electrode layer 319 may each include a conductive metal.

In one or more embodiments, the first electrode layer 318 and the second electrode layer 319 may each include a transparent conductive material. For example, the first electrode layer 318 and the second electrode layer 319 may each include materials such as indium tin oxide (ITO), indium zinc oxide (IZO), indium tin-zinc oxide (ITZO), and the like as the transparent conductive material. When each of the first electrode layer 318 and the second electrode layer 319 includes a transparent conductive material, among light generated in an active layer 313, at least a part of the light that travels toward a first surface 31 0U1 and a second surface 310U2 of the light emitting device core 310 may be transmitted through the first electrode layer 318 and the second electrode layer 319 to be emitted to both end portions of the light emitting device 300_4.

In one or more other embodiments, the first electrode layer 318 and the second electrode layer 319 may each include a conductive material having a high reflectance. For example, each of the first electrode layer 318 and the second electrode layer 319 may include a metal such as silver (Ag), copper (Cu), aluminum (Al), or the like as a material having a high reflectance. When each of the first electrode layer 318 and the second electrode layer 319 includes a conductive material having a high reflectance, among the light generated in the active layer 313, at least a part of the light that travels to both end portions of the light emitting device 300_4 may be reflected from the first electrode layer 318 and the second electrode layer 319.

For example, a travel path of light L, which is generated in the active layer 313, in a case in which each of the first electrode layer 318 and the second electrode layer 319 includes a conductive material having a high reflectance will be described with reference to FIG. 22.

Second light L2, which is generated in the active layer 313 of the light emitting device 300_4 according to one or more embodiments and travels toward the first surface 310U1 and the second surface 310U2 of the light emitting device core 310, may be reflected from the first electrode layer 318 and the second electrode layer 319. The second light L2 may be reflected and may travel toward a second area 310S2 of the light emitting device core 310_4. Accordingly, at least a partial light of the second light L2 that travels toward the first electrode layer 318 and the second electrode layer 319 may be emitted in a display direction DR3 of a display apparatus 10 through the second area 310S2 of the light emitting device core 310_4.

In one or more embodiments, because the light emitting device 300_4 includes the first electrode layer 318 and the second electrode layer 319 each including a conductive material having a high reflectance, the light L2 traveling toward the first surface 310U1 and the second surface 310U2 of the light emitting device core 310_4 may be reflected and may travel toward the display direction DR3 of the display apparatus 10. Thus, the amount of light emitted in the display direction DR3 of the display apparatus 10 is increased, so that the light emitting efficiency of the display apparatus 10 may be improved.

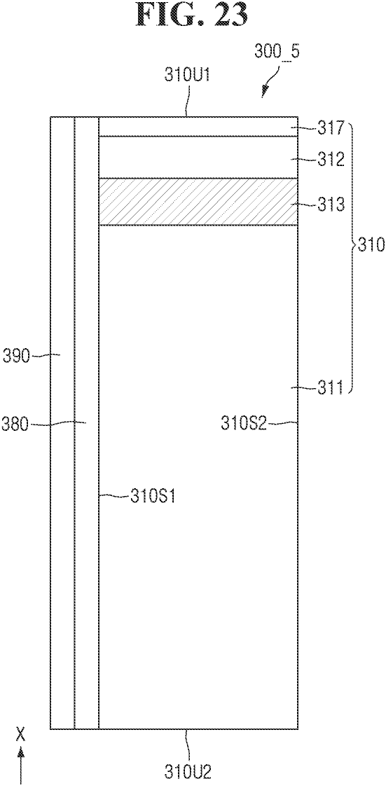

FIG. 23 is a cross-sectional view of a light emitting device according to still one or more other embodiments.

Referring to FIG. 23, a light emitting device 300_5 according to one or more embodiments is different from the light emitting device 300 of FIG. 4 in that a reflective film 390 is further located on a transmission filter layer 380.

Referring to FIG. 23, the light emitting device 300_5 according to one or more embodiments may further include the reflective film 390. The reflective film 390 may be located on the transmission filter layer 380. The reflective film 390 may be located to surround an outer side surface of the transmission filter layer 380. The outer side surface may be an outer surface of the fourth inorganic film 384 (see FIG. 6) of the transmission filter layer 380. The reflective film 390 may be located on a first area 310S1 of a light emitting device core 310. The reflective film 390 may not be located on a second area 310S2 of the light emitting device core 310.

The reflective film 390 serves to reflect at least a part of light, which is generated in an active layer 313 and enters and is transmitted through the transmission filter layer 380 so that the at least partial light re-enters the light emitting device core 310.

The reflective film 390 may include a reflective material. For example, the reflective film 390 may be formed of a material having a high reflectance, such as, silver (Ag), copper (Cu), aluminum (Al), nickel (Ni), lanthanum (La), or the like, but the present disclosure is not limited thereto.

As in the case of one or more embodiments, by further placing the reflective film 390 so as to surround the transmission filter layer 380 on an outer circumferential surface of the transmission filter layer 380, among the light that is generated in the active layer 313 and enters the transmission filter layer 380, at least a partial light transmitted through the transmission filter layer 380 may be reflected toward the second area 310S2 of the light emitting device core 310, so that the amount of light emitted through a side of the second area 310S2 of the light emitting device core 310 may be increased. Thus, the leakage of light may be reduced or minimized, so that the light emitting efficiency of the light emitting device 300_5 may be improved.

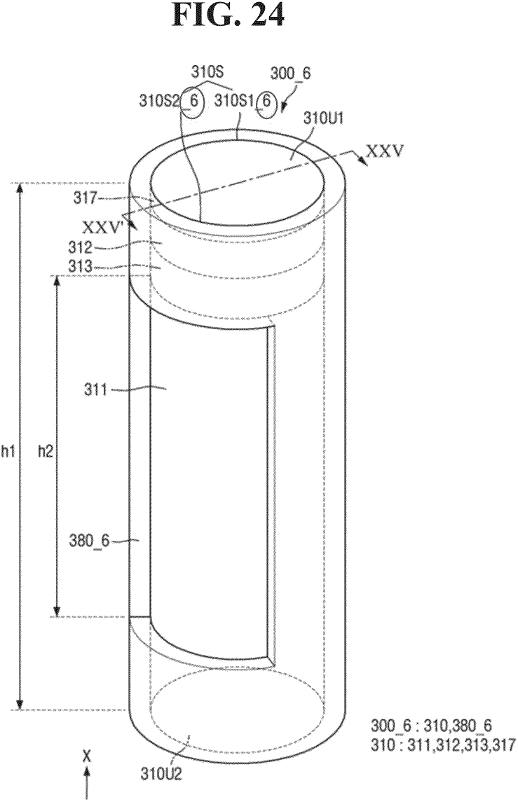

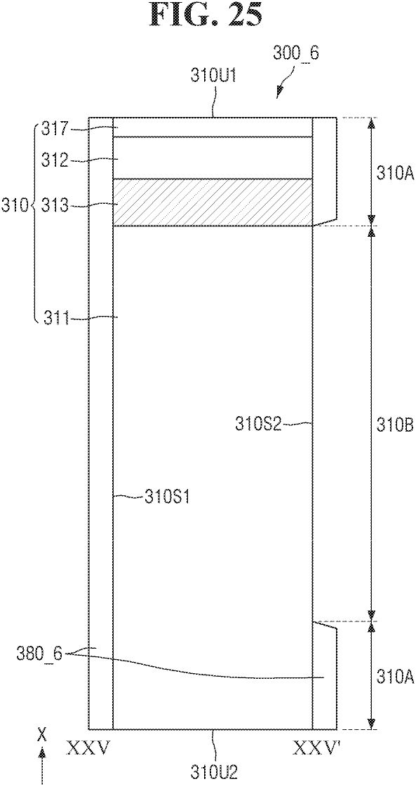

FIG. 24 is a schematic perspective view of a light emitting device according to yet one or more other embodiments. FIG. 25 is a schematic cross-sectional view taken along the line XXV-XXV′ of FIG. 24. Referring to FIGS. 24 and 25, a light emitting device 300_6 according to one or more embodiments is different from the light emitting device 300 of FIGS. 3 and 4 in that a maximum length h1 of a first area 310S1_6 of a light emitting device core 310 is different from a maximum length h2 of a second area 310S2_6.

For example, the first area 310S1 and the second area 310S2 of the light emitting device core 310 according to one or more embodiments may be different in length in one direction X, which is an extending direction of the light emitting device core 310. The maximum length h2 of the second area 31 0S2 in the one direction X may be less than the maximum length h1 of the first area 310S1 in the one direction X.

A transmission filter layer 380_6 may be located to completely surround a side surface of the light emitting device core 310 at both end areas 310A of the light emitting device core 310. The transmission filter layer 380_6 may be located only on a partial area of the side surface of the light emitting device core 310 at a center area 310B of the light emitting device core 310. However, the present disclosure is not limited thereto, and the transmission filter layer 380_6 may be located to completely surround a side surface of each of an electrode layer 317 and a second semiconductor layer 312 located on one end area 310A of the light emitting device core 310. In addition, the transmission filter layer 380_6 may be located to completely surround a part of a side surface of a first semiconductor layer 311 located in the other end area 310A of the light emitting device core 310.

In a cross section of the light emitting device 300_6 according to one or more embodiments taken in the extending direction of the light emitting device core 310, the transmission filter layer 380_6 may be located to surround both end areas 310A of the light emitting device core 310, and the transmission filter layer 380_6 may be located on only one side of the center area 310B of the light emitting device core 310.

In the light emitting device 300_6 according to one or more embodiments, a structure of a cross section perpendicular to the extending direction X of the light emitting device core 310 may be different for each area. For example, in a cross section of each of both end areas 310A of the light emitting device core 310 taken in a direction perpendicular to the one direction X, the transmission filter layer 380_6 may be located to completely surround an outer surface (or side surface) of the light emitting device core 310. On the other hand, in a cross section of the center area 310B of the light emitting device core 310 taken in the direction perpendicular to the one direction X, as shown in FIG. 5, the transmission filter layer 380_6 may be located to expose at least a part of the outer surface (or side surface) of the light emitting device core 310 to the outside.

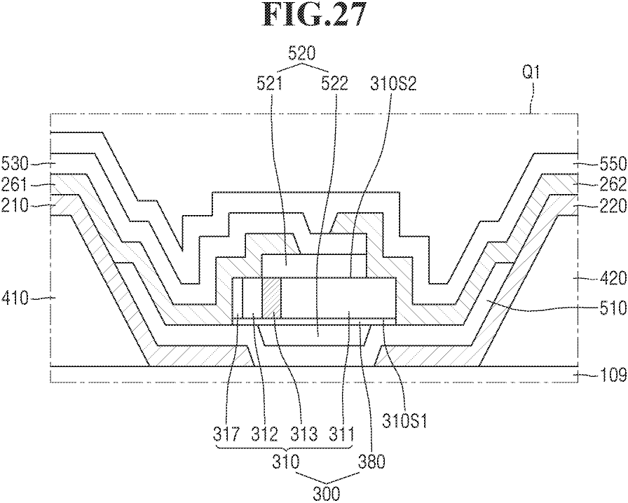

FIG. 26 is a cross-sectional view illustrating an example taken along the line XXVI-XXVI′ of FIG. 2. FIG. 27 is an enlarged cross-sectional view illustrating an example of portion Q1 of FIG. 26.

Referring to FIGS. 2, 26, and 27, the display apparatus 10 may include a circuit device layer and a display device layer located on the substrate 101. A semiconductor layer, a plurality of conductive layers, and a plurality of insulating layers are located on the substrate 101, each of which may constitute the circuit device layer and the display device layer. The plurality of conductive layers may include a first gate conductive layer, a second gate conductive layer, a first data conductive layer, and a second data conductive layer located below a first planarization layer 109 to form the circuit device layer, and electrodes 210 and 220 and contact electrodes 260 located on the first planarization layer 109 to form the display device layer. The plurality of insulating layers may include a first gate insulating layer 103, a first protective layer 105, a first interlayer insulating layer 107, a second interlayer insulating layer 108, the first planarization layer 109, a first insulating layer 510, a second insulating layer 520, a third insulating layer 530, a fourth insulating layer 550, and the like.

The circuit device layer may include circuit devices and a plurality of lines for driving the light emitting device 300, such as, a driving transistor DT, a switching transistor ST, a first conductive pattern CDP, and a plurality of voltage lines VL1 and VL2, and the display device layer may include the light emitting device 300 and may include a first electrode 210, a second electrode 220, a first contact electrode 261, a second contact electrode 262, and the like.

The substrate 101 may be an insulating substrate. The substrate 101 may be made of an insulating material such as glass, quartz, a polymer resin, or the like. In addition, the substrate 101 may be a rigid substrate or a flexible substrate that is bendable, foldable, rollable, and the like.

Light blocking layers BML1 and BML2 may be located on the substrate 101. The light blocking layers BML1 and BML2 may include a first light blocking layer BML1 and a second light blocking layer BML2. The first light blocking layer BML1 and the second light blocking layer BML2 are located to at least overlap a first active material layer DT_ACT of the driving transistor DT and a second active material layer ST_ACT of the switching transistor ST, respectively. The light blocking layers BML1 and BML2 may include light blocking materials to reduce or prevent light that may be incident on the first and second active material layers DT_ACT and ST_ACT. As an example, the first and second light blocking layers BML1 and BML2 may be formed of opaque metal materials that block light transmission. However, the present disclosure is not limited thereto, and in some cases, the light blocking layers BML1 and BML2 may be omitted. Although not shown in the drawing, the first light blocking layer BML1 may be electrically connected to a first source/drain electrode DT_SD1 of the driving transistor DT, which will be described below, and the second light blocking layer BML2 may be electrically connected to a first source/drain electrode ST_SD1 of the switching transistor ST.

A buffer layer 102 may be entirely located on the substrate 101, including the light blocking layers BML1 and BML2. The buffer layer 102 may be formed on the substrate 101 to protect the transistors DT and ST of the pixel PX from moisture permeating through the substrate 101 that is vulnerable to moisture permeation, and may perform a surface planarization function. The buffer layer 102 may be formed as a plurality of inorganic layers that are alternately stacked. For example, the buffer layer 102 may be formed as multiple layers in which inorganic layers including at least one of silicon oxide (SiOₓ), silicon nitride (SiNₓ), and silicon oxynitride (SiON) are alternately stacked.

The semiconductor layer is located on the buffer layer 102. The semiconductor layer may include the first active material layer DT_ACT of the driving transistor DT and the second active material layer ST_ACT of the switching transistor ST. The first active material layer DT_ACT and the second active material layer ST_ACT may be located to partially overlap gate electrodes DT_G and ST_G or the like of the first gate conductive layer to be described below.

In one or more embodiments, the semiconductor layer may include polycrystalline silicon, single-crystal silicon, an oxide semiconductor, and the like. The polycrystalline silicon may be formed by crystallizing amorphous silicon. Examples of the crystallization method include a rapid thermal annealing (RTA) method, a solid phase crystallization (SPC) method, an excimer laser annealing (ELA) method, a metal induced crystallization (MILC) method, a sequential lateral solidification (SLS) method, and the like, but the present disclosure is not limited thereto. When the semiconductor layer includes polycrystalline silicon, the first active material layer DT_ACT may include a first doped area DT_ACTa, a second doped area DT_ACTb, and a first channel area DT_ACTc. The first channel area DT_ACTc may be located between the first doped area DT_ACTa and the second doped area DT_ACTb. The second active material layer ST_ACT may include a third doped area ST_ACTa, a fourth doped area ST_ACTb, and a second channel area ST_ACTc. The second channel area ST_ACTc may be located between the third doped area ST_ACTa and the fourth doped area ST_ACTb. The first doped area DT_ACTa, the second doped area DT_ACTb, the third doped area ST_ACTa, and the fourth doped area ST_ACTb may be areas in which partial areas of each of the first active material layer DT_ACT and the second active material layer ST_ACT are doped with impurities.

In one or more embodiments, the first active material layer DT_ACT and the second active material layer ST_ACT may include an oxide semiconductor. In this case, the doped area of each of the first active material layer DT_ACT and the second active material layer ST_ACT may be an area that has become conductive. The oxide semiconductor may be an oxide semiconductor including indium (In). In some embodiments, the oxide semiconductor may be indium-tin oxide (ITO), indium-zinc oxide (IZO), indium-gallium oxide (IGO), indium-zinc-tin oxide (IZTO), indium-gallium-zinc oxide (IGZO), indium-gallium-tin oxide (IGTO), indium-gallium-zinc-tin oxide (IGZTO), or the like. However, the present disclosure is not limited thereto.

The first gate insulating layer 103 is located on the semiconductor layer and the buffer layer 102. The first gate insulating layer 103 may be located on the buffer layer 102, including the semiconductor layer. The first gate insulating layer 103 may serve as gate insulating films of the driving transistor DT and the switching transistor ST. The first gate insulating layer 103 may be formed as an inorganic layer including an inorganic material such as silicon oxide (SiOₓ), silicon nitride (SiNₓ), and silicon oxynitride (SiON), or in a stacked structure thereof.

The first gate conductive layer is located on the first gate insulating layer 103. The first gate conductive layer may include a first gate electrode DT_G of the driving transistor DT and a second gate electrode ST_G of the switching transistor ST. The first gate electrode DT__G may be located to overlap the first channel area DT_ACTc of the first active material layer DT_ACT in a thickness direction, and the second gate electrode ST__G may be located to overlap the second channel area ST_ACTc of the second active material layer ST_ACT in the thickness direction.

The first gate conductive layer may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

The first protective layer 105 is located on the first gate conductive layer. The first protective layer 105 may be located to cover the first gate conductive layer and may serve to protect the first gate conductive layer. The first protective layer 105 may be formed as an inorganic layer including an inorganic material such as silicon oxide (SiOₓ), silicon nitride (SiNₓ), and silicon oxynitride (SiON), or in a stacked structure thereof.

The second gate conductive layer is located on the first protective layer 105. The second gate conductive layer may include a first capacitor electrode CE1 of a storage capacitor located so that at least a partial area thereof overlaps the first gate electrode DT_G in the thickness direction. The first capacitor electrode CE1 and the first gate electrode DT_G may overlap each other in the thickness direction with the first protective layer 105 interposed therebetween, and the storage capacitor may be formed therebetween. The second gate conductive layer may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

The first interlayer insulating layer 107 is located on the second gate conductive layer. The first interlayer insulating layer 107 may serve as an insulating film between the second gate conductive layer and other layers located thereon. The first interlayer insulating layer 107 may be formed as an inorganic layer including an inorganic material such as silicon oxide (SiOₓ), silicon nitride (SiNₓ), and silicon oxynitride (SiON), or in a stacked structure thereof.

The first data conductive layer is located on the first interlayer insulating layer 107. The first data conductive layer may include the first source/drain electrode DT_SD1 and a second source/drain electrode DT_SD2 of the driving transistor DT, and the first source/drain electrode ST_SD1 and a second source/drain electrode ST_SD2 of the switching transistor ST.

The first source/drain electrode DT_SD1 and the second source/drain electrode DT_SD2 of the driving transistor DT may be in contact with the first doped area DT_ACTa and the second doped area DT_ACTb of the first active material layer DT_ACT, respectively, through contact holes passing through the first interlayer insulating layer 107 and the first gate insulating layer 103. The first source/drain electrode ST_SD1 and the second source/drain electrode ST_SD2 of the switching transistor ST may be in contact with the third doped area ST_ACTa and the fourth doped area ST_ACTb of the second active material layer ST_ACT, respectively, through contact holes passing through the first interlayer insulating layer 107 and the first gate insulating layer 103. In addition, the first source/drain electrode DT_SD1 of the driving transistor DT and the first source/drain electrode ST_SD1 of the switching transistor ST may be electrically connected to the first light blocking layer BML1 and the second light blocking layer BML2, respectively, through other contact holes (not shown). Meanwhile, in the first source/drain electrodes DT_SD1 and ST_SD1 and the second source/drain electrodes DT_SD2 and ST_SD2 of the driving transistor DT and the switching transistor ST, when one electrode is a source electrode, the other electrode may be a drain electrode. However, the present disclosure is not limited thereto, and in the first source/drain electrodes DT_SD1 and ST_SD1 and the second source/drain electrodes DT_SD2 and ST_SD2, when one electrode is a drain electrode, the other electrode may be a source electrode.

The first data conductive layer may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

The second interlayer insulating layer 108 may be located on the first data conductive layer. The second interlayer insulating layer 108 may be entirely located on the first interlayer insulating layer 107 while covering the first data conductive layer and may serve to protect the first data conductive layer. The second interlayer insulating layer 108 may be formed as an inorganic layer including an inorganic material such as silicon oxide (SiOₓ), silicon nitride (SiNₓ), and silicon oxynitride (SiON), or in a stacked structure thereof.

The second data conductive layer is located on the second interlayer insulating layer 108. The second data conductive layer may include a first voltage line VL1, a second voltage line VL2, and the first conductive pattern CDP. A high potential voltage (or a first power voltage VDD) to be supplied to the driving transistor DT may be applied to the first voltage line VL1, and a low potential voltage (or a second power voltage VSS) to be supplied to the second electrode 220 may be applied to the second voltage line VL2. During a manufacturing process of the display apparatus 10, an alignment signal suitable to align the light emitting device 300 may be applied to the second voltage line VL2.

The first conductive pattern CDP may be electrically connected to the first source/drain electrode DT_SD1 of the driving transistor DT through a contact hole formed in the second interlayer insulating layer 108. The first conductive pattern CDP may also be in contact with the first electrode 210, which will be described below, and the driving transistor DT may transmit the first power voltage VDD applied from the first voltage line VL1 to the first electrode 210 through the first conductive pattern CDP. Meanwhile, in the drawing, the second data conductive layer is illustrated as including one first voltage line VL1 and one second voltage line VL2, but the present disclosure is not limited thereto. The second data conductive layer may include a larger number of first voltage lines VL1 and a larger number of second voltage lines VL2.

The second data conductive layer may be formed as a single layer or multiple layers made of one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

The first planarization layer 109 is located on the second data conductive layer. The first planarization layer 109 may include an organic insulating material, for example, an organic material such as polyimide (PI), and may perform a surface planarization function.

The inner banks 410 and 420, the plurality of electrodes 210 and 220, the outer bank 450, the plurality of contact electrodes 260, and the light emitting device 300 are located on the first planarization layer 109. Further, the plurality of insulating layers 510, 520, 530, and 550 may be further located on the first planarization layer 109.

The inner banks 410 and 420 are located on the first planarization layer 109. Each of the first inner bank 410 and the second inner bank 420 may have a structure in which at least a part thereof protrudes with respect to an upper surface of the first planarization layer 109. The protruding portion of each of the first inner bank 410 and the second inner bank 420 may have inclined side surfaces, and light emitted from the light emitting device 300 may travel toward the inclined side surfaces of the inner banks 410 and 420.

When the electrodes 210 and 220 located on the inner banks 410 and 420, respectively, include a material having a high reflectance, the light emitted from the light emitting device 300 may be reflected from the electrodes 210 and 220 located on the side surfaces of the inner banks 410 and 420 to be emitted in an upward direction with respect to the substrate 101. Thus, as described above, the inner banks 410 and 420 may provide an area in which the light emitting device 300 is located and concurrently or substantially simultaneously may serve as a reflective partition wall that reflects the light emitted from the light emitting device 300 upward. In one or more embodiments, the inner banks 410 and 420 may include an organic insulating material such as polyimide (PI), but the present disclosure is not limited thereto.

The plurality of electrodes 210 and 220 are located on the inner banks 410 and 420 and the first planarization layer 109. The first electrode 210 and the second electrode 220 may be located to completely cover outer surfaces of the first inner bank 410 and the second inner bank 420, respectively. In addition, at least a partial area of each of the first electrode 210 and the second electrode 220 may be located directly on the first planarization layer 109.

The first electrode 210 may be in contact with the first conductive pattern CDP through the first contact hole CT1 formed in an area overlapping the outer bank 450 and passing through the first planarization layer 109, and through this, the first electrode 210 may be electrically connected to the first source/drain electrode DT_SD1 of the driving transistor DT.

The second electrode 220 may be in contact with the second voltage line VL2 through the second contact hole CT2 formed in an area overlapping the outer bank 450 and passing through the first planarization layer 109. As shown in the drawing, the second electrodes 220 of the sub-pixels PXn adjacent in the first direction DR1 are electrically connected to each of the second voltage lines VL2 through the second contact holes CT2.

Each of the electrodes 210 and 220 may include a transparent conductive material. As an example, each of the electrodes 210 and 220 may include materials such as indium tin oxide (ITO), indium zinc oxide (IZO), indium tin-zinc oxide (ITZO), and the like, but the present disclosure is not limited thereto.

In some embodiments, each of the electrodes 210 and 220 may include a conductive material having a high reflectance. For example, each of the electrodes 210 and 220 may include a metal such as silver (Ag), copper (Cu), aluminum (Al), or the like as a material having a high reflectance.

However, the present disclosure is not limited thereto, and each of the electrodes 210 and 220 may be formed in a structure in which one or more layers of a transparent conductive material and a metal layer having a high reflectance are stacked, or formed as a single layer including the transparent conductive material and the metal layer. In one or more embodiments, each of the electrodes 210 and 220 may have a stacked structure of ITO/Ag/ITO/IZO or may be an alloy containing Al, nickel (Ni), lanthanum (La), and the like.

The first insulating layer 510 is located on the first planarization layer 109, the first electrode 210, and the second electrode 220. The first insulating layer 510 may be located in a separated space between the electrodes 210 and 220, or between the inner banks 410 and 420. In addition, the first insulating layer 510 may be located on a side opposite to the area between the inner banks 410 and 420 with respect to the inner banks 410 and 420.

The first insulating layer 510 is located to partially cover the first electrode 210 and the second electrode 220. For example, the first insulating layer 510 may be entirely located on the first planarization layer 109, including the first electrode 210 and the second electrode 220, and may be located to expose a part of an upper surface of each of the first electrode 210 and the second electrode 220.

The first insulating layer 510 may protect the first electrode 210 and the second electrode 220, and concurrently or substantially simultaneously, insulate the first electrode 210 from the second electrode 220. In addition, the first insulating layer 510 may reduce or prevent the light emitting device 300 located thereon from being damaged by being in direct contact with other members. However, the shape and structure of the first insulating layer 510 are not limited thereto.

In one or more embodiments, a step difference may be formed on a part of an upper surface of the first insulating layer 510 between the first electrode 210 and the second electrode 220. In some embodiments, the first insulating layer 510 may include an inorganic insulating material, and a part of the upper surface of the first insulating layer 510 located to partially cover the first electrode 210 and the second electrode 220 may be stepped due to the step difference that is formed by the electrodes 210 and 220 located below the first insulating layer 510.

The outer bank 450 may be located on the first insulating layer 510. According to one or more embodiments, a height of the outer bank 450 may be greater than a height of each of the inner banks 410 and 420. As described above, the outer bank 450 may divide adjacent sub-pixels SPXn, and concurrently or substantially simultaneously, reduce or prevent an ink from overflowing to the adjacent sub-pixels SPXn in an inkjet printing process for placing the light emitting device 300 during the manufacturing process of the display apparatus 10. For example, the outer bank 450 may include polyimide (PI), but the present disclosure is not limited thereto.

The light emitting device 300 may be located on the first insulating layer 510 between the inner banks 410 and 420 or between the electrodes 210 and 220. For example, the light emitting device 300 may be located on the first insulating layer 510 located between the inner banks 410 and 420.

However, the present disclosure is not limited thereto, and although not shown in the drawing, at least some of the light emitting devices 300 located in each sub-pixel SPXn may also be located in areas other than an area formed between the inner banks 410 and 420, for example, areas between the inner banks 410 and 420 and the outer bank 450.

The light emitting device 300 may include a plurality of layers located thereon in a direction perpendicular to the upper surface of the substrate 101 or the first planarization layer 109. The light emitting device 300 of the display apparatus 10 according to one or more embodiments may have a shape extending in one direction and may have a structure in which the plurality of semiconductor layers are sequentially located in one direction. The light emitting device 300 may be located such that one direction, in which the light emitting device 300 extends, is parallel to the first planarization layer 109, and the plurality of semiconductor layers included in the light emitting device 300 may be sequentially located in a direction parallel to the upper surface of the first planarization layer 109.

The transmission filter layer 380 may be located between the light emitting device core 310 and the first insulating layer 510. That is, the light emitting device core 310 may be located such that the second area 310S2 faces an upper portion of the display apparatus 10 and the first area 310S1 faces a lower portion of the display apparatus 10.

The second insulating layer 520 may be partially located on the light emitting device 300 located between the first electrode 210 and the second electrode 220. The second insulating layer 520 may include a second upper insulating layer 521 located above the light emitting device 300 and a second lower insulating layer 522 located below the light emitting device 300.

The second upper insulating layer 521 may be in direct contact with the second area 310S2 of the light emitting device core 310. For example, the second upper insulating layer 521 may be located to partially surround the second area 310S2 of the light emitting device core 310 to protect the light emitting device core 310 and concurrently or substantially simultaneously to fix the light emitting device 300 so that the light emitting device 300 is not lost during the manufacturing process of the display apparatus 10.

The second upper insulating layer 521 may be located above the light emitting device 300 and may expose one end portion and the other end portion of the light emitting device 300. The exposed end portions of the light emitting device 300 may be in contact with the contact electrodes 260. Such a shape of the second upper insulating layer 521 may be formed by a patterning process using a material forming the second insulating layer 520 by using a typical mask process. A mask for forming the second upper insulating layer 521 has a width that is less than a length of the light emitting device 300, and the material forming the second upper insulating layer 521 may be patterned to expose both end portions of the light emitting device 300. However, the present disclosure is not limited thereto.

The second lower insulating layer 522 may be located below the first area 310S1 of the light emitting device core 310. The second lower insulating layer 522 may be in direct contact with the transmission filter layer 380 located in the first area 310S1 of the light emitting device core 310. The second lower insulating layer 522 may be formed to fill a space between the first insulating layer 510 and the light emitting device 300, which is formed during the manufacturing process of the display apparatus 10. Accordingly, the second lower insulating layer 522 may be formed to surround an outer surface of the transmission filter layer 380. However, the present disclosure is not limited thereto.

The plurality of contact electrodes 260 and the third insulating layer 530 may be located on the second insulating layer 520.

The first contact electrode 261 and the second contact electrode 262 may be located to be in contact with one end portion and the other end portion of the light emitting device 300, respectively, and concurrently or substantially simultaneously, to cover both side surfaces of the first electrode 210 and the second electrode 220, respectively. As described above, the upper surface of each of the first electrode 210 and the second electrode 220 may be partially exposed, and the first contact electrode 261 and the second contact electrode 262 may be in contact with the exposed upper surfaces of the first electrode 210 and the second electrode 220, respectively.

The first contact electrode 261 and the second contact electrode 262 may be in contact with the semiconductor layers of the light emitting device core 310 exposed by the second upper insulating layer 521. That is, the first contact electrode 261 and the second contact electrode 262 may be in contact with at least some of the semiconductor layers located in the second area 310S2 of the light emitting device core 310. One end portion of the light emitting device 300 may be electrically connected to the first electrode 210 through the first contact electrode 261, and the other end portion thereof may be electrically connected to the second electrode 220 through the second contact electrode 262.

The third insulating layer 530 may be located on the first contact electrode 261. The third insulating layer 530 may be located to cover the first contact electrode 261 and may be located not to overlap a partial area of the light emitting device 300 so that the light emitting device 300 may be connected to the second contact electrode 262. The third insulating layer 530 may be partially in contact with the first contact electrode 261 and the second insulating layer 520 at an upper surface of the second upper insulating layer 521. The third insulating layer 530 may protect the first contact electrode 261 and may concurrently or substantially simultaneously electrically insulate the first contact electrode 261 from the second contact electrode 262.

The second contact electrode 262 is located on the second electrode 220, the second insulating layer 520, and the third insulating layer 530. The second contact electrode 262 may be in contact with the other end portion of the light emitting device 300 and the exposed upper surface of the second electrode 220. The other end portion of the light emitting device 300 may be electrically connected to the second electrode 220 through the second contact electrode 262.

The fourth insulating layer 550 may be entirely located on the substrate 101. The fourth insulating layer 550 may serve to protect members located on the substrate 101 from an external environment.

Each of the first insulating layer 510, the second insulating layer 520, the third insulating layer 530, and the fourth insulating layer 550, which are described above, may include an inorganic insulating material or an organic insulating material. In one or more embodiments, the first insulating layer 510, the second insulating layer 520, the third insulating layer 530, and the fourth insulating layer 550 may each include an inorganic insulating material such as silicon oxide (SiOₓ), silicon nitride (SiNₓ), silicon oxynitride (SiOₓN_{y}), aluminum oxide (Al₂O₃), aluminum nitride (AIN), or the like. Alternatively, the first insulating layer 510, the second insulating layer 520, the third insulating layer 530, and the fourth insulating layer 550 may each include an organic insulating material such as an acrylic resin, an epoxy resin, a phenol resin, a polyamide resin, a Pl resin, an unsaturated polyester resin, a polyphenylene resin, a polyphenylene sulfide resin, benzocyclobutene, a cardo resin, a siloxane resin, a silsesquioxane resin, polymethyl methacrylate, polycarbonate, or a polymethyl methacrylate-polycarbonate synthetic resin. However, the present disclosure is not limited thereto.

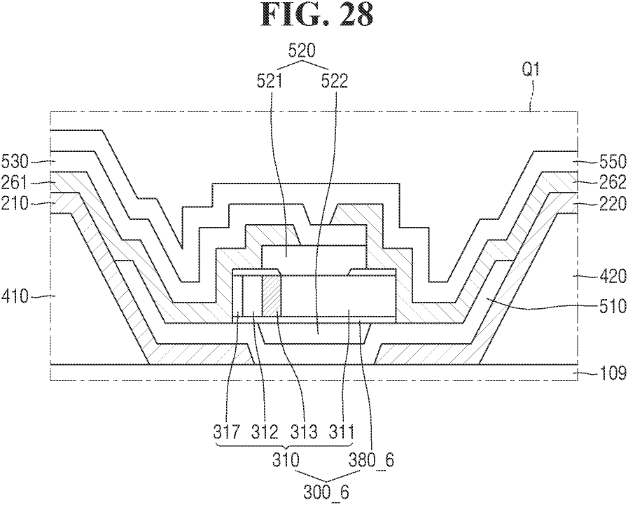

FIG. 28 is an enlarged cross-sectional view illustrating another example of portion Q1 of FIG. 26. FIG. 28 is an enlarged cross-sectional view of a display apparatus 10 including the light emitting device 300_6 of FIG. 25.

Referring to FIG. 28 in conjunction with FIG. 25, the transmission filter layer 380_6 may be located to surround both end areas 310A of the light emitting device core 310 of FIG. 25. Accordingly, in the cross-sectional view of the display apparatus 10, the transmission filter layer 380_6 may be located above and below the light emitting device core 310. That is, the transmission filter layer 380_6 located to surround both end areas 310A of the light emitting device core 310 may be located on one side facing the substrate 101 and the other side opposite to the one side. Accordingly, the second upper insulating layer 521 may be located above the light emitting device core 310 to be in contact with at least a part of the transmission filter layer 380_6.

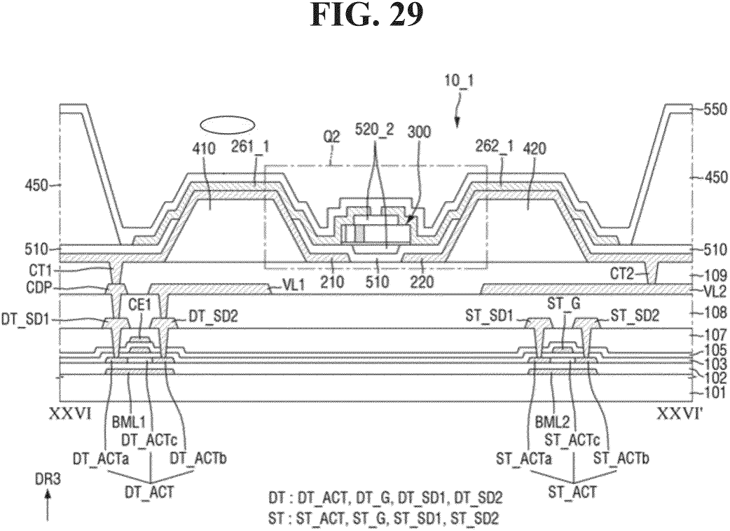

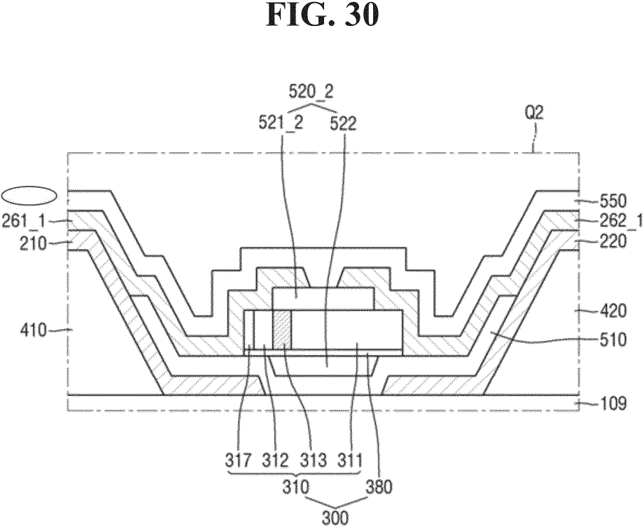

FIG. 29 is a cross-sectional view illustrating another example taken along the line XXVI-XXVI′ of FIG. 2. FIG. 30 is an enlarged cross-sectional view illustrating an example of portion Q2 of FIG. 29.

Referring to FIGS. 29 and 30, in a display apparatus 10_1 according to one or more embodiments, the third insulating layer 530 may be omitted. A difference from one or more embodiments of FIG. 26 is that, in the display apparatus 10_1 of FIG. 29, the third insulating layer 530 is omitted. Hereinafter, repeated descriptions will be omitted, and descriptions will be provided based on differences from the above-described contents.

In the display apparatus 10_1 according to one or more embodiments, the third insulating layer 530 is omitted, and a partial area of a second contact electrode 262_1 may be located directly on a second upper insulating layer 521_2. A first contact electrode 261_1 and the second contact electrode 262_1 may be located to be spaced apart from each other on the second upper insulating layer 521_2. For example, a side surface of the first contact electrode 261_1 and a side surface of the second contact electrode 262_1, which are spaced apart from each other and face each other, may be located on the second upper insulating layer 521_2. The first contact electrode 261_1 may be in contact with one end portion of a light emitting device 300, a first electrode 210, and the second upper insulating layer 521_2, and the second contact electrode 262 may be in contact with the other end portion of the light emitting device 300, a second electrode 220, and the second upper insulating layer 521_2. The contact electrode 261_1 and the second contact electrode 262_1 may be formed together in the same process.

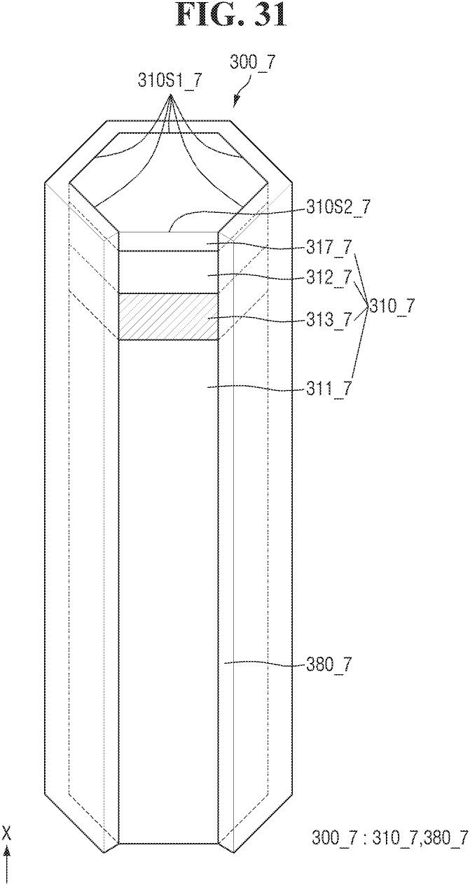

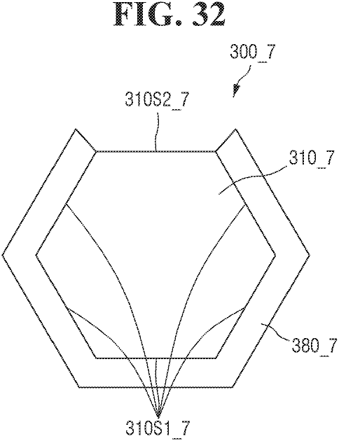

FIG. 31 is a schematic perspective view of a light emitting device according to yet one or more other embodiments. FIG. 32 is a cross-sectional view of the light emitting device of FIG. 31.

Referring to FIGS. 31 and 32, a light emitting device 300_7 according to one or more embodiments is different from the light emitting device 300 of FIGS. 3 to 5 in that a light emitting device core 310_7 has a shape of a hexagonal column.

For example, the light emitting device core 310_7 has a shape extending in one direction X, and a cross-sectional shape of the light emitting device core 310_7 taken in a direction perpendicular to one direction X, which is an extending direction of the light emitting device core 310_7, may be a hexagonal shape. Accordingly, a side surface of the light emitting device core 310_7 may be formed of a plurality of planes rather than a convex curved surface. In one or more embodiments, when the cross-sectional shape of the light emitting device core 310_7 is a hexagonal shape, the light emitting device core 310_7 may include six side surfaces, each of which is formed of a plane.

As described above, a transmission filter layer 380_7 may be located to partially surround the side surfaces of the light emitting device core 310_7. The transmission filter layer 380_7 may be located to expose at least some of the plurality of side surfaces of the light emitting device core 310_7. For example, the transmission filter layer 380_7 may be located to surround five side surfaces of the six side surfaces of the light emitting device core 310_7 but may not be located on one side surface so that the one side surface is exposed. Accordingly, a first area 310S1_7 of the light emitting device core 310_7 includes five side surfaces of the six side surfaces of the light emitting device core 310_7, each of which is formed of a plane, and a second area 310S2_7 of the light emitting device core 310_7 may include one side surface of the six side surfaces of the light emitting device core 310_7, each of which is formed of a plane. However, the present disclosure is not limited thereto, and the transmission filter layer 380_7 may also be located to expose two or more side surfaces of the light emitting device core 310_7. In addition, in the drawing, it is illustrated that the transmission filter layer 380_7 is located to completely expose one side surface of the side surfaces of the light emitting device core 310_7, but the transmission filter layer 380_7 may also be located to expose only a part of the one side surface. In this case, one end and the other end of the transmission filter layer 380_7 may be located to be spaced apart from each other on the one side surface, and the second area 310S2_7 of the light emitting device core 310_7 may be directly exposed in a space in which one end and the other end of the transmission filter layer 380_7 are spaced apart from each other.

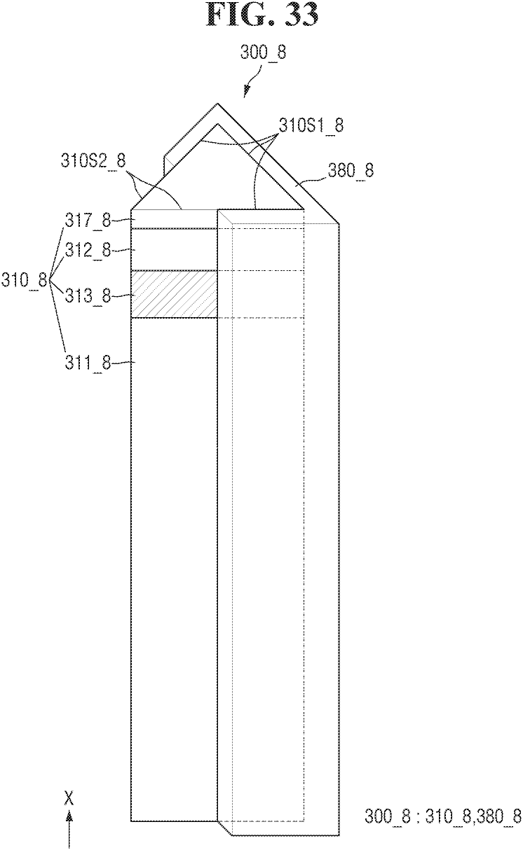

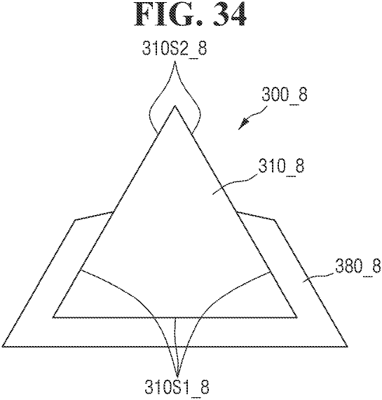

FIG. 33 is a schematic perspective view of a light emitting device according to yet one or more other embodiments. FIG. 34 is a cross-sectional view of the light emitting device of FIG. 33.

Referring to FIGS. 33 and 34, a light emitting device 300_8 according to one or more embodiments is different from the light emitting device 300_7 of FIGS. 31 and 32 in that a light emitting device core 310_8 has a shape of a triangular column.

For example, the light emitting device core 310_8 has a shape extending in one direction X, but a cross-sectional shape of the light emitting device core 310_8 taken in a direction perpendicular to the one direction X, which is an extending direction of the light emitting device core 310_8, may be a triangular shape. In one or more embodiments, when the cross-sectional shape of the light emitting device core 310_8 is a triangular shape, the light emitting device core 310_8 may include three side surfaces, each of which is formed of a plane.

In one or more embodiments, a transmission filter layer 380_8 may be located on the side surfaces of the light emitting device core 310_8, but may be located to completely cover one side surface of the light emitting device core 310_8 and expose at least some of the other two side surfaces. Accordingly, a first area 310S1_8 of the light emitting device core 310_8 includes one side surface of the three side surfaces of the light emitting device core 310_8, each of which is formed of a plane, and a partial area of each of the other two side surfaces adjacent to the one side surface, and a second area 310S2_8 of the light emitting device core 310_8 may include another partial area of each of the other two side surfaces. The second area 310S2_8 of the light emitting device core 310_8 may include a corner opposite to the one side surface of the light emitting device core 370_8, which is completely covered by the transmission filter layer 380_8.

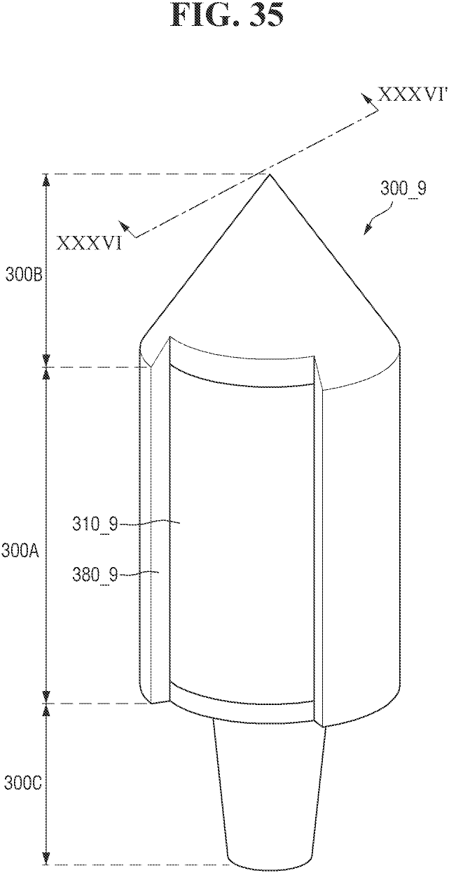

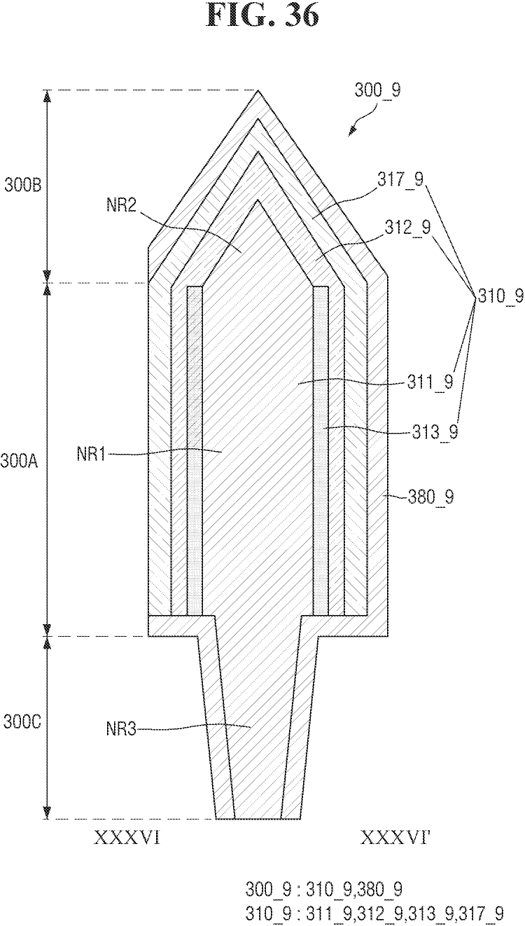

FIG. 35 is a schematic perspective view of a light emitting device according to yet one or more other embodiments. FIG. 36 is a schematic cross-sectional view taken along the line XXXVI-XXXVI′ of FIG. 35.

Referring to FIGS. 35 and 36, a light emitting device 300_9 may have a shape extending in one direction and having a partially inclined side surface. That is, the light emitting device 300_9 according to one or more embodiments may have a partially conical shape.

The light emitting device 300_9 according to one or more embodiments may include a body portion 300A, a first end portion 300B connected to one side of the body portion 300A, and a second end portion 300C connected to the other side of the body portion 300A. The body portion 300A, the first end portion 300B, and the second end portion 300C are referred to define the light emitting device 300_9 or some of semiconductor layers constituting the light emitting device 300_9, and may be integrally formed to form one light emitting device 300_9 rather than separated from each other. That is, the body portion 300A, the first end portion 300B, and the second end portion 300C may be referred to as the light emitting device 300_9 or partial areas of the semiconductor layers constituting the light emitting device 300_9 distinguished from each other. In addition, it may be understood that the body portion 300A, the first end portion 300B, and the second end portion 300C, which will be described below, are not necessarily limited to referring to partial areas of the light emitting device 300_9 including all of the plurality of semiconductor layers, and refer to some components of the light emitting device 300_9, for example, partial areas of a light emitting device core 310_9 including a first semiconductor layer 311_9, an active layer 313_9, a second semiconductor layer 312_9, and the like.

The body portion 300A of the light emitting device 300_9 may have a shape extending in one direction. In some embodiments, the body portion 300A may have a cylindrical shape, a rod shape, or a polygonal columnar shape, but the present disclosure is not limited thereto.

The first end portion 3008 of the light emitting device 300_9 may extend from one side of the body portion 300A of the light emitting device 300_9 to have a shape in which an outer surface thereof is inclined. The inclined outer surface of the first end portion 300B meets at a tip (one point), and the first end portion 300B may have a substantially conical shape.

The second end portion 300C of the light emitting device 300_9 may extend from the other side of the body portion 300A of the light emitting device 300_9 to have a shape in which an outer surface thereof is inclined. The second end portion 300C of the light emitting device 300_9 may have a shape extending in one direction. The second end portion 300C of the light emitting device 300_9 may have a shape similar to that of the body portion 300A of the light emitting device 300_9, and may have a truncated cone shape that decreases in width as it extends away from the body portion 300A of the light emitting device 300_9.

The light emitting device 300_9 may be formed such that a plurality of layers are not stacked in one direction and each of the plurality of layers surrounds an outer surface of another layer. The light emitting device 300_9 may include the light emitting device core 310_9 having at least a partial area extending in one direction, and a transmission filter layer 380_9 that surrounds the light emitting device core 310_9 but exposes at least a partial area of the light emitting device core 310_9.

The first semiconductor layer 311_9 may be located on the body portion 300A, the first end portion 300B, and the second end portion 300C of the light emitting device 300_9. The first semiconductor layer 311_9 may extend in one direction and both end portions thereof may be formed to be inclined toward a center portion thereof. The first semiconductor layer 311_9 may include a first portion NR1 corresponding to the body portion 300A of the light emitting device 300_9, a second portion NR2 corresponding to the first end portion 300B of the light emitting device 300_9, and a third portion NR3 corresponding to the second end portion 300C of the light emitting device 300_9.

The first portion NR1 may have a shape extending in one direction similar to the body portion 300A of the light emitting device 300_9. The first portion NR1 may have substantially the same shape as the body portion 300A.

The second portion NR2 may be a portion positioned on one side of the first portion NR1 and may be formed such that an outer surface thereof is inclined. The second portion NR2 may extend to one side of the first portion NR1 and may be formed such that a cross-sectional side surface thereof is inclined. The second portion NR2 may have a conical shape similar to the first end portion 300B.

The third portion NR3 may be a portion positioned at the other side of the first portion NR1, may have a shape extending in one direction, and may be formed such that a width thereof decreases as it extends away from the first portion NR1 . The third portion NR3 may have a truncated cone shape that decreases in width toward the other end portion of the light emitting device 300_9, similar to the second end portion 300C.

The active layer 313_9 may be located on the body portion 300A of the light emitting device 300_9. The active layer 313_9 may be located to surround an outer surface of the first portion NR1 in the first semiconductor layer 311_9. The active layer 313_9 may have an annular shape extending in one direction. The active layer 313_9 might not be formed on the second portion NR2 and the third portion NR3 of the first semiconductor layer 311_9. Light emitted from the active layer 313_9 may be emitted to both side surfaces of the light emitting device 300_9 with respect to a length direction of the light emitting device 300_9 as well as both end portions of the light emitting device 300_9 in the length direction. The light emitting device 300_9 according to one or more embodiments may emit a relatively large amount of light because the active layer 313_9 has a relatively large area.

The second semiconductor layer 312_9 may be located on the body portion 300A and the first end portion 300B of the light emitting device 300_9. The second semiconductor layer 312_9 may be located to surround an outer surface of the active layer 313_9 located on the body portion 300A and the outer surface of the second portion NR2 of the first semiconductor layer 311_9 located on the first end portion 300B. Thus, the second semiconductor layer 312_9 may include an annular body portion extending in one direction and an upper end portion having a side surface formed to be inclined. The second semiconductor layer 312_9 might not be located on an outer surface of the third portion NR3 of the first semiconductor layer 311_9 located on the second end portion 300C.

An electrode layer 317_9 may be located on the body portion 300A and the first end portion 300B of the light emitting device 300_9. The electrode layer 317_9 may be located to surround an outer surface of the second semiconductor layer 312_9 located on the body portion 300A and the first end portion 300B. The electrode layer 317_9 may have a shape substantially similar to that of the second semiconductor layer 312_9. The electrode layer 317_9 may be in direct contact with the entire surface of the outer surface of the second semiconductor layer 312_9 so as to completely cover the outer surface of the second semiconductor layer 312_9. The electrode layer 317_9 may not be located on the outer surface of the third portion NR3 of the first semiconductor layer 311_9 located on the second end portion 300C.

The transmission filter layer 380_9 may be located on an outer surface of the light emitting device core 310_9 and may be located to expose at least a part of the outer surface of the light emitting device core 310_9. The transmission filter layer 380_9 may be located on the body portion 300A, the first end portion 300B, and the second end portion 300C of the light emitting device 300_9. The transmission filter layer 380_9 may be located to completely surround the first end portion 300B and the second end portion 300C of the light emitting device 300_9, and may not be located on at least a part of the body portion 300A of the light emitting device 300_9. The transmission filter layer 380_9 may be located to surround an outer surface of the electrode layer 317_9 located on the first end portion 300B and to surround the outer surface of the third portion NR3 of the first semiconductor layer 311_9 located on the second end portion 300C. The transmission filter layer 380_9 may be located to expose at least a part of the outer surface of the electrode layer 317_9 located on the body portion 300A.

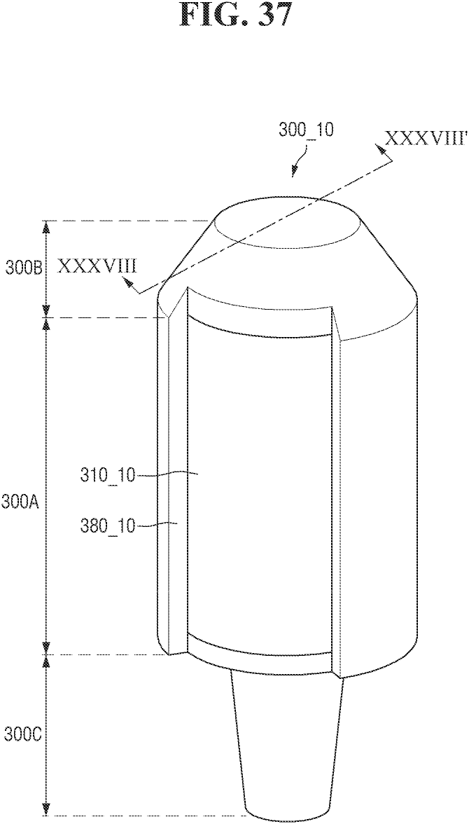

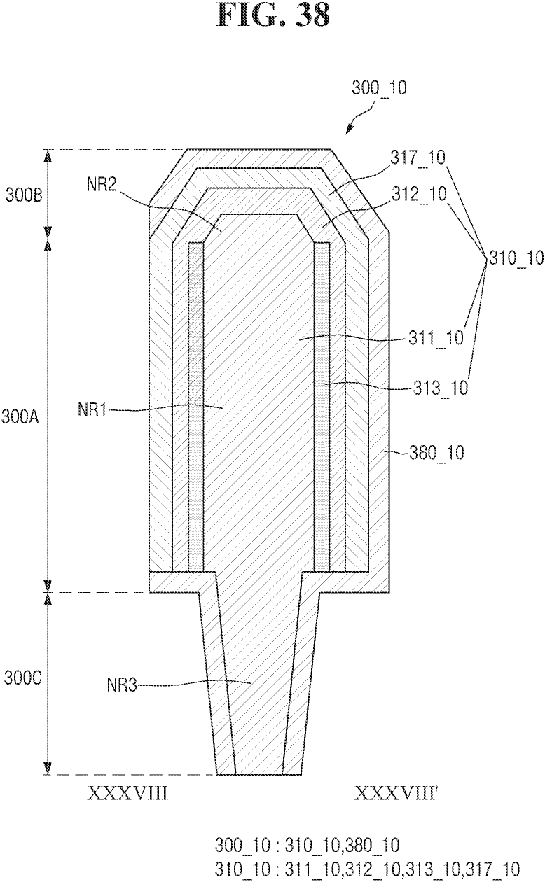

FIG. 37 is a schematic perspective view of a light emitting device according to yet one or more other embodiments. FIG. 38 is a schematic cross-sectional view taken along the line XXXVIII-XXXVIII′ of FIG. 37.

Referring to FIGS. 37 and 38, a light emitting device 300_10 according to one or more embodiments is different from the light emitting device 300_9 of FIGS. 35 and 36 in that a first end portion 300B has a truncated cone shape. For example, in the light emitting device 300_10, the first end portion 300B may have a truncated cone shape that decreases in width as it extends away from a body portion 300A. A second portion NR2 of a first semiconductor layer 311_10 located on the first end portion 300B of the light emitting device 300_10 may be formed such that a width thereof decreases as it extends away from the first portion NR1, similar to the shape of the first end portion 300B. That is, the second portion NR2 of the first semiconductor layer 311_10 may have a truncated cone shape that decreases in width toward one end portion of the light emitting device 300_10. Accordingly, in the first end portion 300B, a shape of each of a second semiconductor layer 312_10, an electrode layer 317_10, and a transmission filter layer 380_10, which are located to surround an outer surface of the first semiconductor layer 311_10 and are sequentially stacked, may be similar to that of the first semiconductor layer 311_10.

In concluding the detailed description, those skilled in the art will appreciate that many variations and modifications can be made to the embodiments without substantially departing from the principles of the present disclosure. Therefore, the disclosed embodiments of the present disclosure are used in a generic and descriptive sense only and not for purposes of limitation.

1. A light emitting device comprising:
a light emitting device core extending along one direction; and
a transmission filter layer surrounding a part of a side surface of the light emitting device core,
wherein the side surface of the light emitting device core includes:
a first area in which the transmission filter layer is located; and
a second area in which the transmission filter layer is not located.

2. The light emitting device of claim 1, wherein the transmission filter layer has different reflectances depending on an incident angle based on a wavelength and a normal direction of incident light.

3. The light emitting device of claim 2, wherein the transmission filter layer includes one or more optical layers,
wherein the optical layers include a first inorganic film having a first refractive index, and a second inorganic film having a second refractive index that is different from the first refractive index, which are sequentially stacked at the second area in a direction perpendicular to the one direction.

4. The light emitting device of claim 3, wherein the first refractive index is less than the second refractive index.

5. The light emitting device of claim 1, wherein the light emitting device core includes a first semiconductor layer, a second semiconductor layer, and an active layer located between the first semiconductor layer and the second semiconductor layer.

6. The light emitting device of claim 5, wherein the first semiconductor layer, the active layer, and the second semiconductor layer are sequentially located along the one direction.

7. The light emitting device of claim 6, wherein the light emitting device core further includes:
a first electrode layer locatedabove or below the first semiconductor layer; and
a second electrode layer located above or below the second semiconductor layer,
wherein each of the first electrode layer and the second electrode layer includes a conductive material having a high reflectance.

8. The light emitting device of claim 6, wherein the second area includes at least a part of a side surface of the active layer.

9. The light emitting device of claim 1, further comprising a reflective film on an outer circumferential surface of the transmission filter layer.

10. The light emitting device of claim 1, wherein a surface of the second area is exposed by the transmission filter layer.

11. The light emitting device of claim 1, wherein an outer circumferential length of the first area is greater than an outer circumferential length of the second area.

12. The light emitting device of claim 11, wherein a length of the first area in the one direction is equal to a length of the light emitting device core in the one direction.

13. The light emitting device of claim 12, wherein a maximum length of the second area in the one direction is less than the length of the first area in the one direction.

14. The light emitting device of claim 1, wherein a thickness of the transmission filter layer located in an area adjacent to the second area decreases from the first area toward the second area.

15. The light emitting device of claim 1, wherein a surface of the second area includes a surface unevenness.

16. The light emitting device of claim 1, wherein the transmission filter layer is in direct contact with the first area.

17. A display apparatus comprising:
a substrate;
a first electrode located on the substrate;
a second electrode located on the substrate to be spaced apart from the first electrode;
a light emitting device located between the first electrode and the second electrode and electrically connected to the first electrode and the second electrode; and
an insulating layer located on the light emitting device,
wherein the light emitting device includes:
a light emitting device core extending along one direction; and
a transmission filter layer surrounding a part of a side surface of the light emitting device core,
wherein the side surface of the light emitting device core includes:
a first area in which the transmission filter layer is located: and
a second area in which the transmission filter layer is not located.

18. The display apparatus of claim 17, wherein the one direction is parallel to an upper surface of the substrate, and
the light emitting device is located such that the second area faces a side opposite to one side facing the substrate.

19. The display apparatus of claim 18, wherein the first area is located on the one side facing the substrate, and
the transmission filter layer is located between the light emitting device core and the substrate.

20. The display apparatus of claim 18, wherein the insulating layer is in contact with the second area.
